(19) United States
(12) Patent Application Publication
(10) Pub. No.: US 2025/0296069 A1
(43) Pub. Date: Sep. 25, 2025

(54) SYSTEMS AND METHODS FOR GENERATION OF HYPERPOLARIZED MATERIALS

(71) Applicant: NVISION IMAGING TECHNOLOGIES GMBH, Ulm (DE)

(72) Inventors: Ilai SCHWARTZ, Neu-Ulm (DE); Stephan KNECHT, Stuttgart (DE); Jochen SCHEUER, Stuttgart (DE)

(73) Assignee: NVISION IMAGING TECHNOLOGIES GMBH, Ulm (DE)

(21) Appl. No.: 18/863,303

(22) PCT Filed: May 5, 2023
(86) PCT No.: PCT/IB2023/054714

§ 371 Date: Nov. 5, 2024

Related U.S. Application Data
(60) Provisional application No. 63/364,268, filed on May 6, 2022.

(51) Int. Cl. B01J 19/24; B01J 10/00; C01B 3/00; F17C 1/00; G01R 33/28; G01R 33/46

(52) U.S. Cl. CPC B01J 19/245; B01J 10/00; C01B 3/0089; F17C 1/00; G01R 33/282; G01R 33/46; F17C 2201/0104; F17C 2221/012; F17C 2223/0161; F17C 2223/035; F17C 2227/0135; F17C 2227/0302; F17C 2270/0536

(57) ABSTRACT

Systems and methods are disclosed for containing parahydrogen. In some of the systems and methods, a gas cylinder is configured to contain hydrogen gas therein. The hydrogen gas may include parahydrogen gas at a first concentration of at least 45% and a pressure of at most 40 bar. The parahydrogen gas may have a decay time constant of at least 30 days. The parahydrogen gas may be for use in a PHIP, PHIP-SAH, SABRE, or PHIPNOESYS NMR or MRI experiment. In some of the systems and methods, a cryogenic chamber is configured to contain liquid hydrogen therein. The liquid hydrogen may include liquid parahydrogen at a concentration of at least 50 mole percent. The liquid hydrogen may be boiled to generate hydrogen gas containing at least 50 mole percent parahydrogen gas. The parahydrogen gas may be for use in a PHIP, PHIP-SAH, SABRE, or PHIPNOESYS NMR or MRI experiment.

### CROSS-REFERENCE

The present application claims priority to U.S. Provisional Patent Application No. 63/364,268, filed on May 6, 2022, entitled “Parahydrogen gas obtained from liquid hydrogen,” which is incorporated herein by reference in its entirety for all purposes.

### TECHNICAL FIELD

The disclosed embodiments generally relate to generation of hyperpolarized materials for use in nuclear magnetic resonance (NMR), magnetic resonance imaging (MRI), or similar applications.

### BACKGROUND

Nuclear magnetic resonance (NMR) and magnetic resonance imaging (MRI) are technologies with vital applications in chemistry, biology, and medical imaging. Despite these successes, it is recognized that magnetic resonance applications may often have limitations due to the minute nuclear polarization of analytes (typically on the order of 10⁻⁵). This minute nuclear polarization can result in limited sensitivity in comparison to other analytic techniques such as mass spectrometry.

Increasing nuclear spin polarization beyond its thermal equilibrium value can greatly improve magnetic resonance sensitivity. Nuclear spin polarization can be increased using known techniques like parahydrogen induced polarization (PHIP), PHIP-sidearm hydrogenation (PHIP-SAH), and signal amplification by reversible exchange (SABRE). Using such techniques, the nuclear spin polarization of a material can be increased 10,000 times or more. The enhanced nuclear spin polarization can result in a proportional increase in the NMR/MRI signal. While this enhanced polarization decays over time due to the relaxation time of the nuclear spins in the polarized molecules, for many molecules the relaxation time can be on the order of seconds to minutes, during which increased polarization can lead to a dramatic increase in NMR/MRI signal sensitivity. By enabling such a dramatic increase in NMR/MRI signal sensitivity, increased nuclear spin polarization can enable new applications, such as the imaging of in vivo metabolism using metabolites with increased nuclear spin polarization in an MRI scanner, accelerate NMR spectroscopy investigations, and enable visualization of previously unseen molecular dynamics and structures.

### SUMMARY

In accordance with the present disclosure, hydrogen gas containing parahydrogen gas can be contained within a gas cylinder at a relatively low pressure and optionally a relatively low volume. The parahydrogen gas can then be used by an end user, such as a hospital or clinic, in a nuclear magnetic resonance (NMR) or magnetic resonance imaging (MRI) experiment. For instance, the parahydrogen gas can be used by an end user in a parahydrogen-induced polarization (PHIP), PHIP-sidearm hydrolysis (PHIP-SAH), signal amplification by reversible exchange (SABRE), or PHIP nuclear Overhauser effect system (PHIPNOESYS) experiment. The relatively low pressure may permit the parahydrogen gas to decay into orthohydrogen gas at a relatively low rate, allowing sufficient time for the gas cylinder to be shipped to an end user and for the end user to use the parahydrogen gas in a PHIP, PHIP-SAH, SABRE, or PHIPNOESYS experiment. The combination of relatively low pressure and optionally a relatively low volume may allay safety concerns associated with the use of flammable gases at high pressures.

In accordance with the present disclosure, liquid hydrogen containing a high percentage of liquid parahydrogen can be generated and contained within a cryogenic container. The liquid hydrogen can then be boiled to obtain hydrogen gas containing a high percentage of parahydrogen gas. The parahydrogen gas can then be used by an end user, such as a hospital or clinic, in an NMR or MRI experiment. In some cases, the liquid hydrogen can be stored at a central distribution facility, such as a supply station. The liquid hydrogen can be boiled and used to fill gas cylinders or other gas canisters with hydrogen containing a high percentage of parahydrogen gas. The parahydrogen gas can then be used by an end user. For instance, the parahydrogen gas can be used by an end user in a PHIP, PHIP-SAH, SABRE, or PHIPNOESYS experiment. Due to the very long lifetime of liquid parahydrogen, using liquid hydrogen containing a high percentage of liquid parahydrogen may allow for greatly enhanced shelf life for the parahydrogen source and may significantly simply supply chain logistics associated with distributing parahydrogen to end users.

The disclosed embodiments include a system for containing parahydrogen gas. The system may include a gas cylinder configured to contain hydrogen gas therein. The hydrogen gas may include parahydrogen gas at a first concentration of at least 45% and a pressure of at most 20 bar. The parahydrogen gas may have a decay time constant of at least 30 days. The parahydrogen gas may be for use in a PHIP, PHIP-SAH, SABRE, or PHIPNOESYS NMR or MRI experiment.

The disclosed embodiments include a method for containing parahydrogen gas. The method may include containing hydrogen gas within a gas cylinder. The hydrogen gas may include parahydrogen gas at a first concentration of at least 45% and a pressure of at most 20 bar. The parahydrogen gas may have a decay time constant of at least 30 days. The parahydrogen gas may be for use in a PHIP, PHIP-SAH, SABRE, or PHIPNOESYS NMR or MRI experiment.

The disclosed embodiments include a system for generating parahydrogen gas. The system may include a cryogenic container. The cryogenic container may be configured to contain liquid hydrogen therein. The system may include a chamber fluidically coupled to the cryogenic chamber. The chamber may be configured to receive liquid hydrogen from the cryogenic container. The chamber may be configured to boil the received liquid hydrogen and to thereby form a first hydrogen gas comprising at least 50 mole percent (mol %) parahydrogen gas. The parahydrogen gas may be for use in a PHIP, PHIP-SAH, SABRE, or PHIPNOESYS NMR or MRI experiment.

The disclosed embodiments include a method for generating parahydrogen gas. The method may include receiving liquid hydrogen and boiling the liquid hydrogen to thereby form a first hydrogen gas comprising at least 50 mol % parahydrogen gas. The parahydrogen gas may be for use in a PHIP, PHIP-SAH, SABRE, or PHIPNOESYS NMR or MRI experiment.

It is to be understood that both the foregoing general description and the following detailed description are exemplary and explanatory only and are not restrictive of the disclosed embodiments, as claimed.

### BRIEF DESCRIPTION OF THE DRAWINGS

The accompanying drawings, which comprise a part of this specification, illustrate several embodiments and, together with the description, serve to explain the principles and features of the disclosed embodiments. In the drawings:

FIG. 1 depicts a first exemplary system for providing parahydrogen gas for use in a parahydrogen induced polarization (PHIP), PHIP-sidearm hydrolysis (PHIP-SAH), signal amplification by reversible exchange (SABRE), or PHIP nuclear Overhauser effect system (PHIPNOESYS) application, in accordance with disclosed embodiments.

FIG. 2 depicts an exemplary decay curve showing the relationship between parahydrogen shelf life and hydrogen gas pressure for hydrogen gas comprising an initial parahydrogen concentration of 95%, in accordance with disclosed embodiments.

FIG. 3 shows exemplary decay curves showing parahydrogen shelf life for a variety of gas cylinder purging conditions, in accordance with disclosed embodiments.

FIG. 4 depicts a first exemplary method for providing parahydrogen gas for use in a PHIP, PHIP-SAH, SABRE, or PHIPNOESYS application, in accordance with disclosed embodiments.

FIG. 5A depicts a second exemplary system for providing parahydrogen gas for use in a PHIP, PHIP-SAH, SABRE, or PHIPNOESYS application, in accordance with disclosed embodiments.

FIG. 5B depicts a third exemplary system for providing parahydrogen gas for use in a PHIP, PHIP-SAH, SABRE, or PHIPNOESYS application, in accordance with disclosed embodiments.

FIG. 6A depicts a second exemplary method for providing parahydrogen gas for use in a PHIP, PHIP-SAH, SABRE, or PHIPNOESYS application, in accordance with disclosed embodiments.

FIG. 6B depicts a third exemplary method for providing parahydrogen gas for use in a PHIP, PHIP-SAH, SABRE, or PHIPNOESYS application, in accordance with disclosed embodiments.

FIG. 7 depicts an exemplary Raman spectrum of a hydrogen gas mixture containing more than 90% parahydrogen generated from liquid hydrogen, in accordance with disclosed embodiments.

### DETAILED DESCRIPTION

Reference will now be made in detail to exemplary embodiments, discussed with regards to the accompanying drawings. In some instances, the same reference numbers will be used throughout the drawings and the following description to refer to the same or like parts. Unless otherwise defined, technical and/or scientific terms have the meaning commonly understood by one of ordinary skill in the art. The disclosed embodiments are described in sufficient detail to enable those skilled in the art to practice the disclosed embodiments. It is to be understood that other embodiments may be utilized and that changes may be made without departing from the scope of the disclosed embodiments. Thus, the materials, methods, and examples are illustrative only and are not intended to be necessarily limiting.

NMR and MRI can be used in a wide variety of applications including, but not limited to, the determination of chemical structures in synthetic intermediates, the determination of the atomic-level structure and dynamics in proteins and nucleic acids, minimally invasive imaging of biological tissues or organisms, and even metabolic analyses of biological tissues or organisms. However, NMR and MRI can have limited sensitivity due to a combination of the minute size of nuclear magnetic moments and the correspondingly small polarization at thermal equilibrium. This limited sensitivity can prevent the use of NMR and MRI in some applications and can render other applications of NMR and MRI impractically time- or material-consuming.

NMR and MRI sensitivity can be increased through the use of higher magnetic fields and optimized detection systems. However, an alternative approach is to increase NMR and MRI sensitivity by increasing nuclear spin polarization to levels significantly greater than thermal equilibrium. Such hyperpolarization techniques can often increase the NMR and MRI sensitivity by a factor that is significantly greater than increasing the magnetic field or using optimized detection systems.

Nuclear spin polarization can be increased using a variety of techniques, including dynamic nuclear polarization (DNP), parahydrogen-induced polarization (PHIP), PHIP-sidearm hydrolysis (PHIP-SAH), signal amplification by reversible exchange (SABRE), PHIP nuclear Overhauser effect system (PHIPNOESYS), spin-exchange optical pumping (SEOP), optically initialized electron triplet states (also referred to as photoexcited triplet states, PETS), and other suitable methods. Among these techniques, parahydrogen-based methods such as PHIP, PHIP-SAH, SABRE, and PHIPNOESYS are especially promising, as they can be performed at high throughput using relatively low-cost equipment.

For instance, recent work in NMR and MRI has demonstrated that NMR and MRI signals associated with a variety of biorelevant imaging agents can be enhanced by many orders of magnitude using PHIP or PHIP-SAH. Such drastic signal enhancement allows spectroscopic analysis of the biorelevant imaging agent as it is metabolized by various tissues at different locations within a body. Analysis of the metabolic information determined by such spectroscopic imaging may allow non-invasive determination of a health state of tissue within a body. For example, abnormal metabolism of the biorelevant imaging agent may be indicative of a disease such as cancer at some location in the body.

In PHIP and PHIP-SAH, a derivative (e.g., a precursor) of a molecule of interest is reacted with parahydrogen to form a parahydrogenated form of the derivative. Spin order is then transferred from the protons added via the parahydrogenation reaction to a nucleus of interest (such as a carbon-13 nucleus) contained within the molecule of interest. In PHIP, the parahydrogenated form of the derivative is chemically identical to the molecule of interest and distinguished from the molecule of interest only by the spin order derived from the parahydrogenation reaction. In PHIP-SAH, the parahydrogenated form of the derivative is cleaved (e.g., hydrolyzed) to yield the hyperpolarized molecule of interest. In SABRE, the molecule of interest itself forms a coordination complex with a polarization transfer catalyst and parahydrogen. Spin order is then transferred from the parahydrogen to a nucleus of interest within the molecule of interest via the coordination complex. The molecule of interest is then optionally purified and used in an NMR or MRI procedure. PHIPNOESYS utilizes PHIP or PHIP-SAH to generate a hyperpolarized material (e.g., the source compound) and transfers polarization from the source compound to the material used in NMR spectroscopy (e.g., the target compound, target molecule, or molecule of interest). The transfer of polarization from source compound to target compound proceeds via the intermolecular nuclear Overhauser effect (NOE). PHIPNOESYS has been shown to increase signals in NMR spectroscopy by up to a factor of nearly 2,000, allowing for application of NMR spectroscopy at significantly reduced concentrations than would otherwise be achievable.

Each of PHIP, PHIP-SAH, SABRE, and PHIPNOESYS requires a source of parahydrogen that serves as the source of spin order that allows hyperpolarization of the nucleus of interest. A high concentration of parahydrogen is typically created by cooling gaseous hydrogen (for instance, to a temperature below 77 degrees Kelvin (K), 25 K, or lower) in the presence of a paramagnetic catalyst. At room temperature, gaseous hydrogen contains about 25% parahydrogen (which is useful for PHIP, PHIP-SAH, SABRE, and PHIPNOESYS) and about 75% orthohydrogen (which is not useful for PHIP, PHIP-SAH, SABRE, and PHIPNOESYS). At significantly colder temperatures, orthohydrogen is converted to parahydrogen, increasing the concentration of parahydrogen in the hydrogen gas (for instance, the concentration of parahydrogen is about 50% at 77 K and greater than 98% at 25 K). In most current research, the hydrogen gas is then warmed and either used immediately in a PHIP, PHIP-SAH, SABRE, or PHIPNOESYS experiment, or stored in a high-pressure gas cylinder for later use in such an experiment.

As PHIP, PHIP-SAH, SABRE, and PHIPNOESYS move into more routine use, such as in clinical applications, it will be necessary for end users, such as hospitals or clinics, to have access to a reliable source of parahydrogen gas. However, it is difficult for such end users to purchase and maintain the equipment necessary to produce parahydrogen on-site due to the safety concerns associated with cryogenics, high pressure, and the use of a highly flammable gas such as hydrogen. The high pressure and flammability concerns also apply to the idea of shipping high-pressure cylinders full of parahydrogen gas to such end users. Moreover, parahydrogen readily converts to orthohydrogen at high pressures, requiring end users to use their parahydrogen supplies quickly. Thus, shipping high-pressure cylinders full of parahydrogen to end users is also not ideal. Accordingly, there is a need for new systems and methods that allow parahydrogen to be shipped to end users while allaying safety and time concerns.

The disclosed embodiments contain hydrogen gas comprising parahydrogen within a gas cylinder at a relatively low pressure and optionally a relatively low volume. The parahydrogen gas can then be used by an end user, such as a hospital or clinic, in an NMR or MRI experiment. For instance, the parahydrogen gas can be used by an end user in a PHIP, PHIP-SAH, SABRE, or PHIPNOESYS experiment. The relatively low pressure may permit the parahydrogen gas to decay into orthohydrogen gas at a relatively low rate, allowing sufficient time for the gas cylinder to be shipped to an end user and for the end user to use the parahydrogen gas in a PHIP, PHIP-SAH, SABRE, or PHIPNOESYS experiment. The combination of relatively low pressure and optionally a relatively low volume may allay safety concerns associated with the use of flammable gases at high pressures. As described herein, the disclosed embodiments can be used for polarizing molecules of interest.

The disclosed embodiments generate and contain liquid hydrogen comprising a high percentage of liquid parahydrogen within a cryogenic container. The liquid hydrogen can then be boiled to obtain hydrogen gas containing a high percentage of parahydrogen gas. The parahydrogen gas can then be used by an end user, such as a hospital or clinic, in an NMR or MRI experiment. In some cases, the liquid hydrogen can be stored at a central distribution facility, such as a supply station. In some embodiments, the liquid hydrogen can be stored at a mobile distribution facility, such as an automobile-based or truck-based distribution facility. The liquid hydrogen can be boiled and used to fill gas cylinders or other gas canisters with hydrogen containing a high percentage of parahydrogen gas. The parahydrogen gas can then be used by an end user. For instance, the parahydrogen gas can be used by an end user in a PHIP, PHIP-SAH, SABRE, or PHIPNOESYS experiment. Due to the very long lifetime of liquid parahydrogen, using liquid hydrogen containing a high percentage of liquid parahydrogen may allow for greatly enhanced shelf life for the parahydrogen source and may significantly simply supply chain logistics associated with distributing parahydrogen to end users.

### Hyperpolarization and Parahydrogen

As used in the present disclosure, “polarization” refers to an imbalance in electron or nuclear spins orientations. In some embodiments, polarization can be the normalized, approximate difference in the number of spins in a first direction minus a number of spins in the opposite direction. As a non-limiting example, given 200,000 ¹H nuclear spins, a polarization of 2% can correspond to 102,000 spins in the first direction and 98,000 in the opposite direction. In some embodiments, “hyperpolarization” can include polarization of a species (e.g., nuclear, election, or the like) in excess of typical polarization levels for that species observed at thermal equilibrium subject to exposure to a specified magnetic field. As a non-limiting example, a sample in a 1 T magnetic field at thermal equilibrium, with ¹H nuclear spin polarization in excess of 0.000341% can be hyperpolarized to have a ¹H nuclear spin polarization substantially higher (e.g., at least one or more orders of magnitude higher) than the 0.000341% thermal equilibrium polarization. As an additional nonlimiting example, a sample in a 3 T magnetic field at thermal equilibrium, with ¹³C spin polarization in excess of 0.000257% can be hyperpolarized. As a further nonlimiting example, a sample in a 3 T magnetic field at thermal equilibrium, with ¹⁵N spin polarization in excess of 0.000103% can be hyperpolarized.

As used in the present disclosure, “hyperpolarization” describes a condition in which an absolute value of a difference between a population of spin states (e.g., nuclear spin states, proton spin states, or the like) being in one state (e.g., spin up) and a population of a spin states being in another state (e.g., spin down) exceeds the absolute value of the corresponding difference at thermal equilibrium.

Parahydrogen can be used as a source of polarization, consistent with disclosed embodiments. Parahydrogen, as described herein, is a form of molecular hydrogen in which the two proton spins are in the singlet state. The disclosed embodiments are not limited to a particular method of generating parahydrogen. Parahydrogen may be formed in a gas form or in a liquid form. In some embodiments, parahydrogen is generated in gas form by flowing hydrogen gas at low temperature through a chamber with a catalyst (e.g., iron oxide or another suitable catalyst). The hydrogen gas can contain both parahydrogen and orthohydrogen. The low temperature can bring the hydrogen gas to thermodynamic equilibrium in the chamber, increasing the population of parahydrogen.

As used in the present disclosure, a population difference between two spin states is the difference between the population of the two spin states divided by the total population of the two spin states. A population difference may be expressed as a fractional population difference or a percentage population difference. In some embodiments, the fractional population difference is at least about 0.1, 0.2, 0.3, 0.4, 0.5, 0.6, 0.7, 0.8, 0.9, or more, at most about 0.9, 0.8, 0.7, 0.6, 0.5, 0.4, 0.3, 0.2, 0.1, or less, or within a range defined by any two of the preceding values.

Hydrogen gas can exhibit a population difference between proton spin states which greatly exceeds the population difference between proton spin states at thermal equilibrium. Hydrogen gas containing a high concentration of parahydrogen can have a large population difference between the singlet spin state and any of the triplet spin states. In the case of Iz1Iz2 order, there is a large population difference, for example, between the spin state |T↑>|↓> and the spin state |↑>↑>. The population difference in proton spin states can be at least about 0.1 (e.g., a 10% difference in spin states or 55% of the parahydrogen molecules in a sample being in the singlet state and 45% in the triplet state), 0.2, 0.3, 0.4, 0.5, 0.6, 0.7, 0.8, 0.9, or more, at most about 0.9, 0.8, 0.7, 0.6, 0.5, 0.4, 0.3, 0.2, 0.1, or less, or within a range defined by any two of the preceding values.

### Systems for Providing Low-Pressure Parahydrogen Gas

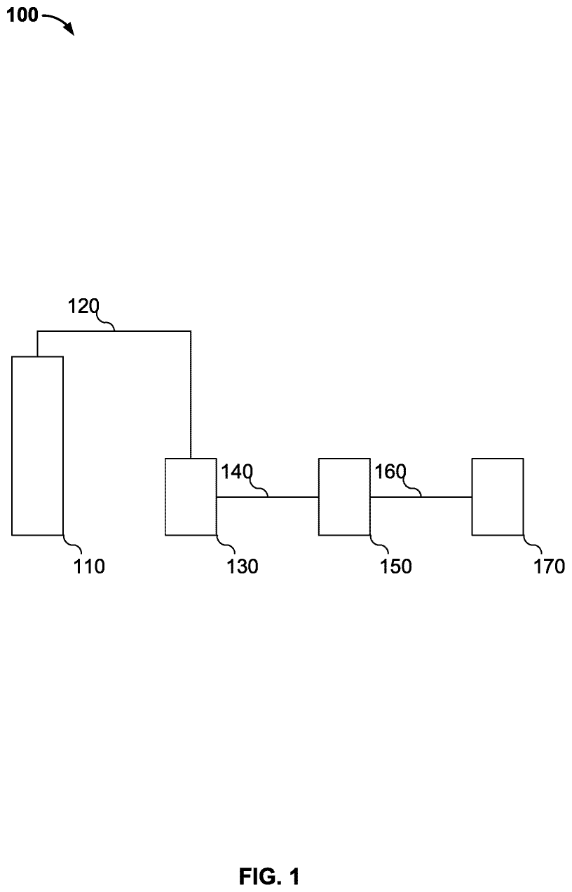

FIG. 1 depicts a first exemplary system 100 for providing parahydrogen gas for use in a PHIP, PHIP-SAH, SABRE, or PHIPNOESYS NMR or MRI application, in accordance with disclosed embodiments. In the example shown, the system 100 comprises a gas cylinder 110. In some embodiments, the gas cylinder 110 is configured to contain hydrogen gas therein. In some embodiments, the gas cylinder 110 contains hydrogen gas therein.

In some embodiments, the hydrogen gas comprises parahydrogen gas at a first concentration. In some embodiments, the first concentration is at least about 40%, 45%, 50%, 55%, 60%, 65%, 70%, 75%, 80%, 85%, 90%, 95%, 99%, 99.5%, 99.9%, or more. In some embodiments, the first concentration is at most about 99.9%, 99.5%, 99%, 95%, 90%, 85%, 80%, 75%, 70%, 65%, 60%, 55%, 50%, 45%, 40%, or less. In some embodiments, the first concentration is within a range defined by any two of the preceding values. For instance, in some embodiments, the first concentration is between about 45% and about 99.9%, about 45% and about 99.5%, about 45% and about 99%, about 45% and about 95%, about 45% and about 90%, about 50% and about 99.9%, about 50% and about 99.5%, about 50% and about 99%, about 50% and about 95%, about 50% and about 90%, or the like. In some embodiments, the first concentration is measured as the fractional percentage of hydrogen molecules in the parahydrogen state. For instance, a first concentration of 45% means that 45% of the hydrogen molecules are in the parahydrogen state and 55% of the hydrogen molecules are in the orthohydrogen state. The first concentration may be measured on a volume to volume (v/v), weight to weight (w/w), mole percent (mol %), or another basis.

In some embodiments, the hydrogen gas comprises a pressure of at most about 100 bar, 95 bar, 90 bar, 85 bar, 80 bar, 75 bar, 70 bar, 65 bar, 60 bar, 55 bar, 50 bar, 45 bar, 40 bar, 35 bar, 30 bar, 25 bar, 20 bar, 19 bar, 18 bar, 17 bar, 16 bar, 15 bar, 14 bar, 13 bar, 12 bar, 11 bar, 10 bar, 9 bar, 8 bar, 7 bar, 6 bar, 5 bar, 4 bar, 3 bar, 2 bar, 1 bar, or less. In some embodiments, the hydrogen gas comprises a pressure of at least about 1 bar, 2 bar, 3 bar, 4 bar, 5 bar, 6 bar, 7 bar, 8 bar, 9 bar, 10 bar, 11 bar, 12 bar, 13 bar, 14 bar, 15 bar, 16 bar, 17 bar, 18 bar, 19 bar, 20 bar, 25 bar, 30 bar, 35 bar, 40 bar, 45 bar, 50 bar, 55 bar, 60 bar, 65 bar, 70 bar, 75 bar, 80 bar, 85 bar, 90 bar, 95 bar, 100 bar, or more. In some embodiments, the hydrogen gas comprises a pressure that is within a range defined by any two of the preceding values. For instance, in some embodiments, the hydrogen gas comprises a pressure between about 1 bar and about 40 bar, about 1 bar and about 35 bar, about 1 bar and about 30 bar, about 1 bar and about 30 bar, about 1 bar and about 20 bar, about 1 bar and about 15 bar, about 1 bar and about 10 bar, about 1 bar and about 5 bar, about 1 bar and about 4 bar, about 1 bar and about 3 bar, about 1 bar and about 2 bar, about 2 bar and about 40 bar, about 2 bar and about 35 bar, about 2 bar and about 30 bar, about 2 bar and about 25 bar, about 2 bar and about 20 bar, about 2 bar and about 15 bar, about 2 bar and about 10 bar, about 2 bar and about 5 bar, about 2 bar and about 4 bar, about 2 bar and about 3 bar, about 3 bar and about 40 bar, about 3 bar and about 35 bar, about 3 bar and about 30 bar, about 3 bar and about 25 bar, about 3 bar and about 20 bar, about 3 bar and about 15 bar, about 3 bar and about 10 bar, about 3 bar and about 5 bar, about 3 bar and about 4 bar, about 4 bar and about 40 bar, about 4 bar and about 35 bar, about 4 bar and about 30 bar, about 4 bar and about 20 bar, about 4 bar and about 20 bar, about 4 bar and about 15 bar, about 4 bar and about 10 bar, about 4 bar and about 5 bar, about 5 bar and about 40 bar, about 5 bar and about 35 bar, about 5 bar and about 30 bar, about 5 bar and about 25 bar, about 5 bar and about 20 bar, about 5 bar and about 15 bar, about 5 bar and about 10 bar, about 10 bar and about 40 bar, about 10 bar and about 35 bar, about 10 bar and about 30 bar, about 10 bar and about 25 bar, about 10 bar and about 20 bar, about 10 bar and about 15 bar, about 15 bar and about 40 bar, about 15 bar and about 35 bar, about 15 bar and about 30 bar, about 15 bar and about 25 bar, about 15 bar and about 20 bar, about 20 bar and about 40 bar, about 20 bar and about 35 bar, about 20 bar and about 30 bar, about 20 bar and about 25 bar, about 25 bar and about 40 bar, about 25 bar and about 35 bar, about 25 bar and about 30 bar, about 30 bar and about 40 bar, about 30 bar and about 35 bar, about 35 bar and about 40 bar, or the like.

In some embodiments, the hydrogen gas has a volume of at most about 250 standard liters, 240 standard liters, 230 standard liters, 220 standard liters, 210 standard liters, 200 standard liters, 190 standard liters, 180 standard liters, 170 standard liters, 160 standard liters, 150 standard liters, 140 standard liters, 130 standard liters, 120 standard liters, 110 standard liters, 100 standard liters, 95 standard liters, 90 standard liters, 85 standard liters, 80 standard liters, 75 standard liters, 70 standard liters, 65 standard liters, 60 standard liters, 55 standard liters, 50 standard liters, 45 standard liters, 40 standard liters, 35 standard liters, 30 standard liters, 25 standard liters, 20 standard liters, 15 standard liters, 10 standard liters, 5 standard liters, 1 standard liters, or less. In some embodiments, the hydrogen gas has a volume of at least 1 standard liters, 5 standard liters, 10 standard liters, 15 standard liters, 20 standard liters, 25 standard liters, 30 standard liters, 35 standard liters, 40 standard liters, 45 standard liters, 50 standard liters, 55 standard liters, 60 standard liters, 65 standard liters, 70 standard liters, 75 standard liters, 80 standard liters, 85 standard liters, 90 standard liters, 95 standard liters, 100 standard liters, 110 standard liters, 120 standard liters, 130 standard liters, 140 standard liters, 150 standard liters, 160 standard liters, 170 standard liters, 180 standard liters, 190 standard liters, 200 standard liters, 210 standard liters, 220 standard liters, 230 standard liters, 240 standard liters, 250 standard liters, or more. In some embodiments, the hydrogen gas has a volume that is within a range defined by any two of the preceding values.

In some embodiments, the parahydrogen gas has a decay time constant of at least about 30 days, 35 days, 40 days, 45 days, 50 days, 55 days, 60 days, 65 days, 70 days, 75 days, 80 days, 85 days, 90 days, 95 days, 100 days, 110 days, 120 days, 130 days, 140 days, 150 days, 160 days, 170 days, 180 days, 190 days, 200 days, 225 days, 250 days, 275 days, 300 days, 325 days, 350 days, 375 days, 400 days, 425 days, 450 days, 475 days, 500 days, 525 days, 550 days, 575 days, 600 days, or more. In some embodiments, the parahydrogen gas has a decay time constant of at most about 600 days, 575 days, 550 days, 525 days, 500 days, 475 days, 450 days, 425 days, 400 days, 375 days, 350 days, 325 days, 300 days, 275 days, 250 days, 225 days, 200 days, 190 days, 180 days, 170 days, 160 days, 150 days, 140 days, 130 days, 120 days, 110 days, 100 days, 95 days, 90 days, 85 days, 80 days, 75 days, 70 days, 65 days, 60 days, 55 days, 50 days, 45 days, 40 days, 35 days, 30 days, or less. In some embodiments, the parahydrogen gas has a decay time constant that is within a range defined by any two of the preceding values. In some embodiments, the decay time constant represents the decay time constant for conversion of parahydrogen molecules into orthohydrogen molecules. In some embodiments, the decay time constant is given by r in the decay equation C(t)−C_{eq}=(C(t=0)−C_{eq})exp(−t/τ), where C(t) is the parahydrogen concentration at time t, C(t=0) is the initial parahydrogen concentration (i.e., the parahydrogen concentration at time t=0), and C_{eq} is the thermal equilibrium parahydrogen concentration (approximately 25% at room temperature).

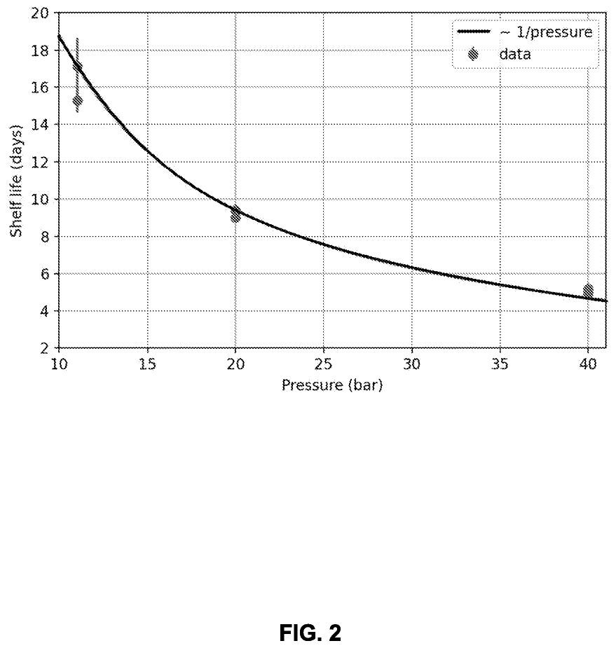

FIG. 2 depicts an exemplary decay curve showing the relationship between parahydrogen shelf life and hydrogen gas pressure for hydrogen gas comprising an initial parahydrogen concentration of 95%, in accordance with disclosed embodiments. The shelf life t_{shelf} was arbitrarily defined as the amount of time required for the parahydrogen concentration to decrease from its initial 95% concentration to a final concentration of 85%. That is, t_{shelf}=ln((0.95−0.25)/(0.85−0.25))τ≅0.154τ. As shown in FIG. 2, the shelf life rapidly decreases with increasing hydrogen gas pressure. Thus, in some embodiments, the relatively low pressure may permit the parahydrogen gas to decay into orthohydrogen gas at a relatively low rate, allowing sufficient time for the gas cylinder to be shipped to an end user (such as a hospital or clinic) and for the end user to use the parahydrogen gas in a PHIP, PHIP-SAH, SABRE, or PHIPNOESYS experiment. Additionally, the combination of relatively low pressure and optionally a relatively low volume may allay safety concerns associated with the use of flammable gases at high pressures, greatly simplifying the logistics of supplying end users with parahydrogen for their PHIP, PHIP-SAH, SABRE, or PHIPNOESYS experiment.

Returning to the discussion of FIG. 1, in some embodiments, the gas cylinder 110 has been purged by at least one purging operation prior to containing the hydrogen gas therein. In some embodiments, the at least one purging operation comprises at least one evacuation operation. In some embodiments, the at least one evacuation operation is performed by evacuating the gas cylinder 110 with a vacuum pump, such as a rotary pump, scroll pump, cryopump, turbomolecular pump, ion pump, getter pump, or the like.

In some embodiments, the at least one purging operation comprises at least one heating operation. In some embodiments, the at least one heating operation comprises heating the gas cylinder 110. In some embodiments, the gas cylinder 110 is heated to a temperature of at least about 30 degrees Celsius (° C.), 40° C., 50° C., 60° C., 70° C., 80° C., 90° C., 100° C., or more, at most about 100° C., 9 0° C., 80° C., 70° C., 60° C., 50° C., 40° C., 30° C., or less, or a temperature that is within a range defined by any two of the preceding values. In some embodiments, the at least one heating operation is performed prior to, during, or after the at least one evacuation operation.

In some embodiments, the at least one purging operation comprises at least one filling operation. In some embodiments, the at least one filling operation is performed by filling the gas cylinder 110 with at least one gas. In some embodiments, the at least one gas comprises an inert gas, such as nitrogen or argon. In some embodiments, the at least one gas comprises hydrogen. In some embodiments, the at least one gas comprises hydrogen with an increased concentration of parahydrogen when compared to thermal equilibrium parahydrogen concentration. In some embodiments, the gas has a purity of at least about 95%, 99%, 99.9%, 99.95%, 99.99%, 99.995%, 99.999%, 99.9995%, 99.9999%, or more, at most about 99.9999%, 99.9995%, 99.999%, 99.995%, 99.99%, 99.95%, 99.9%, 99.5%, 99%, 95%, or less, or a purity that is within a range defined by any two of the preceding values. In some embodiments, the at least one filling operation is performed prior to or after the at least one evacuation operation or the at least one heating operation. In some embodiments, the at least one filling operation is following by venting the gas cylinder 110.

In some embodiments, the at least one purging operation reduces the concentration of impurities or contaminants within the gas cylinder 110 prior to filling the gas cylinder 110 with the hydrogen gas containing the parahydrogen. In some embodiments, the at least one purging operation reduces the concentration of oxygen, nitrogen, trace gases such as carbon dioxide, water vapor, and the like.

In some embodiments, the gas cylinder 110 has been purged with at least about 1, 2, 3, 4, 5, 6, 7, 8, 9, 10, 11, 12, 13, 14, 15, 16, 17, 18, 19, 20, or more purging operations prior to containing the hydrogen gas therein. In some embodiments, the gas cylinder 110 has been purged with at most about 20, 19, 18, 17, 16, 15, 14, 13, 12, 11, 10, 9, 8, 7, 6, 5, 4, 3, 2, or 1 purging operations prior to containing the hydrogen gas therein. In some embodiments, the gas cylinder 110 has been purged with a number of purging operations that is within a range defined by any two of the preceding values prior to containing the hydrogen gas therein.

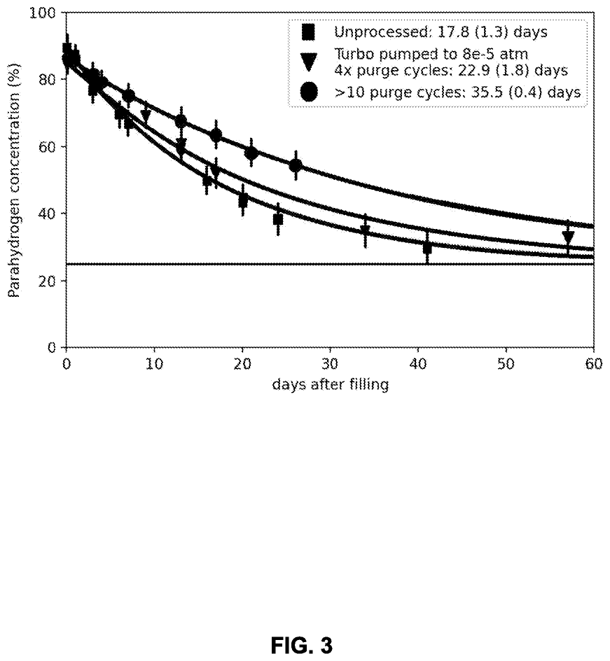

FIG. 3 shows exemplary decay curves showing parahydrogen shelf life for a variety of gas cylinder purging conditions, in accordance with disclosed embodiments. A gas cylinder was pumped out using a vacuum pump, subjected to a variety of washing conditions, and filled with hydrogen gas containing an initial parahydrogen concentration of 90%. The washing conditions were: (1) unprocessed (no heating or filling operations) (“Unprocessed” in FIG. 3), (2) four alternating cycles of evacuation operations (with a turbomolecular pump) and filling operations (“Turbo pumped to 8e-5 atm 4× purge cycles” in FIG. 3), and (3) more than ten alternating cycles of evacuation operations (with a turbomolecular pump) and filling operations (“>10 purge cycles” in FIG. 3). As shown in FIG. 3, decay constants were: (1) 17.8±3 days, (2) 22.9±1.8 days, and (3) 35.5±0.4 days. Thus, purging the gas cylinder prior to filling with hydrogen gas can greatly improve the lifetime of the parahydrogen.

Returning to the discussion of FIG. 1, in some embodiments, the system 100 further comprises a parahydrogen generation apparatus (not shown in FIG. 1). In some embodiments, the parahydrogen generation apparatus is coupled to the gas cylinder 110 during filling of the gas cylinder 110 with the hydrogen gas. In some embodiments, the parahydrogen generation apparatus is configured to generate hydrogen gas comprising the parahydrogen gas at any first concentration described herein. In some embodiments, the parahydrogen generation apparatus comprises a parahydrogen generation apparatus as described in WO2022157534, which is incorporated herein by reference in its entirety for all purposes.

In some embodiments, the system 100 further comprises a first flow system 120. In some embodiment, the first flow system 120 is fluidically coupled to the gas cylinder 110. In some embodiments, the first flow system 120 is configured to receive the parahydrogen gas from the gas cylinder 110. In some embodiments, the first flow systems comprises one or more gas pressure regulators, gas flow tubes, gas flow pumps, and/or gas flow valves configured to determine a flow rate at which the parahydrogen gas flows from the gas cylinder 110 through the first flow system 120. In some embodiments, the first flow system 120 comprises at least one compressor. In some embodiments, the at least one compressor is configured to increase a pressure of the parahydrogen gas above the pressure of the parahydrogen gas as supplied by the gas cylinder 110. In some embodiments, increasing the pressure of the parahydrogen gas after storage increases the efficiency with which the parahydrogen gas can be used in a PHIP, PHIP-SAH, SABRE, or PHIPNOESYS procedure.

In some embodiments, the system 100 further comprises a mixing chamber 130. In some embodiments, the mixing chamber 130 is fluidically coupled to the first flow system 120. In some embodiments, the first flow system 120 is configured to direct the parahydrogen gas from the gas cylinder 110 to the mixing chamber 130. In some embodiments, the mixing chamber 130 is configured to contain a first solution therein.

In some embodiments, the first solution is configured to generate a molecule of interest for use in a PHIP or PHIP-SAH experiment. In such embodiments, the first solution comprises a molecule of interest or a derivative (e.g., a precursor) of the molecule of interest. In some embodiments, the molecule of interest is for use in an NMR or MRI procedure. In some embodiments, the mixing chamber 130 is configured to mix the parahydrogen gas with the molecule of interest or the derivative of the molecule of interest. In some embodiments, the molecule of interest comprises any biorelevant imaging agent described herein.

In some embodiments, the mixing chamber 130 is configured to mix the parahydrogen gas into the first solution, such that the parahydrogen gas mixes with the molecule of interest. In some embodiments, the first solution contains a polarization transfer catalyst, such as [IrCl(COD)(IMes)], where COD is cis,cis-1,5-cycloctadiene and IMes is 1,3-bis(2,4,6-trimethylphenyl)imidazol-2-ylidine. In some embodiments, the parahydrogen gas is mixed with the molecule of interest in the presence of the polarization transfer catalyst. In some embodiments, the mixture of the parahydrogen gas with the molecule of interest in the presence of the polarization transfer catalyst transfers spin order from the parahydrogen gas to the molecule of interest via a SABRE interaction.

In some embodiments, the derivative of the molecule of interest comprises at least one double bond or triple bond. In some embodiments, the mixing chamber 130 is configured to mix the parahydrogen gas into the first solution, such that the parahydrogen gas mixes with the derivative of the molecule of interest. In some embodiments, the first solution contains a hydrogenation catalyst. In some embodiments, the parahydrogen gas is mixed with the derivative of the molecule of interest in the presence of the hydrogenation catalyst. In some embodiments, the mixture of the parahydrogen gas with the derivative of the molecule of interest in the presence of the hydrogenation catalyst induces a parahydrogenation reaction between the parahydrogen gas and the derivative of the molecule of interest.

In some embodiments, the parahydrogenation reaction hydrogenates the at least one double bond or triple bond and forms the molecule of interest. In some embodiments, spin order from the parahydrogen gas is transferred to the molecule of interest via a PHIP interaction. Examples of PHIP interactions can be found in, for instance, WO2022157534 and WO2022018514, each of which is incorporated herein by reference in its entirety for all purposes.

In some embodiments, the parahydrogenation reaction hydrogenates the at least one double bond or triple bond and forms a parahydrogenated derivative of the molecule of interest. In some embodiments, the parahydrogenated derivative of the molecule of interest is mixed with a hydrolysis agent, such as sodium hydroxide (NaOH) or potassium hydroxide (KOH). In some embodiments, the hydrolysis agent hydrolyzes the parahydrogenated derivative of the molecule of interest, forming a hydrolyzed sidearm and the molecule of interest via a PHIP-SAH interaction. Examples of PHIP-SAH interactions can be found in, for instance, WO2022157534, WO2022018514, and WO2021198776, each of which is incorporated herein by reference in its entirety for all purposes.

In some embodiments, the system 100 further comprises a second flow system 140. In some embodiments, the second flow system 140 is fluidically coupled to the mixing chamber 130. In the example shown, the second flow system 140 comprises one or more liquid flow tubes, liquid flow pumps, and/or liquid flow valves configured to determine a flow rate at which the first solution flows from the mixing chamber 130.

In some embodiments, the system 100 further comprises a hydrolysis chamber 150. In some embodiments, the second flow system 140 is configured to direct the first solution to the hydrolysis chamber 150. In some embodiments, the hydrolysis chamber 150 is configured to contain the first solution after it is flowed through the second flow system 140 to the hydrolysis chamber 150. In some embodiments, the hydrolysis chamber 150 is configured to mix the first solution with the hydrolysis agent to thereby hydrolyze the parahydrogenated derivative of the molecule of interest.

Although depicted as utilizing the second flow system 140 to flow the first solution to the hydrolysis chamber 150 in FIG. 1, the system 100 need not be configured in such a manner. For instance, the second flow system 140 may be configured to direct the hydrolysis agent to the mixing chamber 130 and the hydrolysis chamber 150 may be omitted. In such case, the hydrolysis agent flows to the mixing chamber 130 and hydrolysis of the parahydrogenated derivative of the molecule of interest occurs in the mixing chamber 130.

In some embodiments, the system 100 further comprises a third flow system 160. In some embodiments, the third flow system 160 is fluidically coupled to the hydrolysis chamber 150. In the example shown, the second flow system 160 comprises one or more liquid flow tubes, liquid flow pumps, and/or liquid flow valves configured to determine a flow rate at which the first solution flows from the hydrolysis chamber 150.

In some embodiments, the system 100 further comprises a purification chamber 170. In some embodiments, the second flow system 160 is configured to direct the first solution to the hydrolysis chamber 170. In some embodiments, the purification chamber 170 is configured to contain the first solution after it is flowed through the third flow system 160 to the purification chamber 170. In some embodiments, the purification chamber 170 is configured to mix the first solution with a second solution to thereby form a third solution containing the molecule of interest. In some embodiments, the third solution comprises a reduced concentration of contaminants compared with the first solution.

In some embodiments, the purification chamber 170 is configured to perform a precipitation reaction on the first solution. In some embodiments, the precipitation reaction forms a precipitate of the molecule of interest. In some embodiments, the purification chamber 170 is configured to mix the precipitate with the second solution to thereby form the third solution. Examples of precipitation reactions are described in, for instance, WO2022018514 and WO2022269350, each of which is incorporated herein by reference in its entirety for all purposes.

Although depicted as utilizing the third flow system 160 to flow the first solution to the purification chamber 170 in FIG. 1, the system 100 need not be configured in such a manner. For instance, the third flow system 160 may be configured to direct the second solution to the hydrolysis chamber 150 and the purification chamber 170 may be omitted. In such case, the second solution flows to the hydrolysis chamber 150 and purification of the molecule of interest occurs in the hydrolysis chamber 150. Alternatively, the third flow system 160 may be configured to direct the second solution to the mixing chamber 130 and both the hydrolysis chamber 150 and the purification chamber 170 may be omitted. In such case, the second solution flows to the mixing chamber 130 and purification of the molecule of interest occurs in the mixing chamber 130.

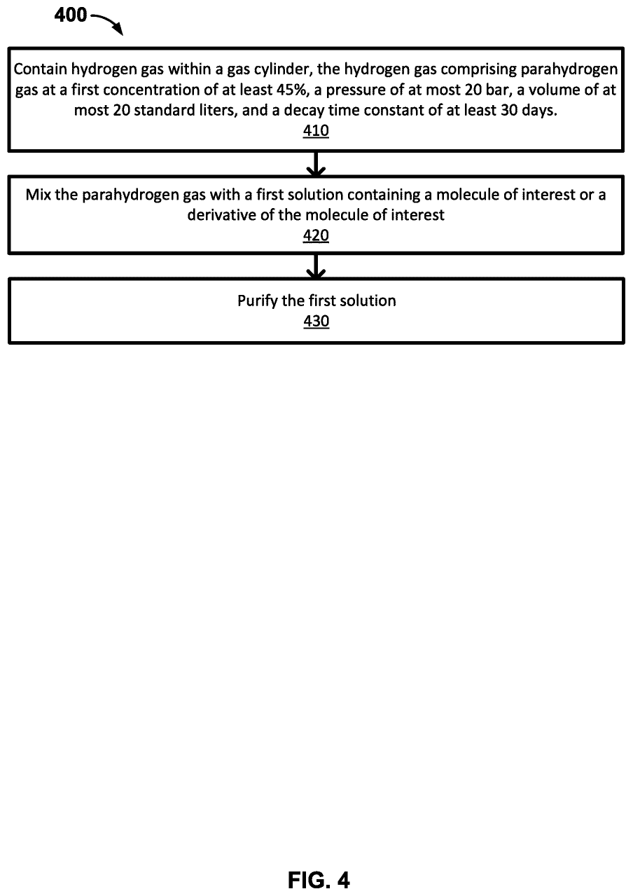

In some embodiments, system 100 is configured to implement the method 400 described herein with respect to FIG. 4.

### Methods for Providing Low-Pressure Parahydrogen Gas

FIG. 4 depicts a first exemplary method 400 for providing parahydrogen gas for use in a PHIP, PHIP-SAH, SABRE, or PHIPNOESYS NMR or MRI application, in accordance with disclosed embodiments. In some embodiments, method 400 is performed using system 100 described herein with respect to FIG. 1.

At step 410, hydrogen gas is contained within a gas cylinder. In some embodiments, the hydrogen gas comprising parahydrogen at any first concentration described herein. In some embodiments, the hydrogen gas comprising any pressure described herein. In some embodiments, the parahydrogen gas has any decay time constant described herein. In some embodiments, the hydrogen gas has any volume described herein. In some embodiments, the parahydrogen gas is for use in a PHIP, PHIP-SAH, SABRE, or PHIPNOESYS NMR or MRI procedure, as described herein. In some embodiments, the gas cylinder has been purged with any number of purging operations described herein prior to containing the hydrogen gas within the gas cylinder. In some embodiments, the method 400 comprising purging the gas cylinder with any number of purging operations described herein prior to containing the hydrogen gas within the gas cylinder.

At step 420, the parahydrogen gas is mixed with any first solution described herein. In some embodiments, the pressure of the parahydrogen gas is increased above the pressure of the parahydrogen gas as supplied by the gas cylinder prior to mixing the parahydrogen gas with the first solution.

In some embodiments, the parahydrogen gas is mixed with any molecule of interest described herein in the presence of any polarization transfer catalyst described herein. In some embodiments, such mixing transfers spin order from the parahydrogen gas to the molecule of interest via a SABRE interaction, as described herein. In some embodiments, the molecule of interest comprises any molecule of interest described herein.

In some embodiments, the parahydrogen gas is mixed with any derivative of any molecule of interest described herein in the presence of any hydrogenation catalyst described herein. In some embodiments, such mixing induces a parahydrogenation reaction between the parahydrogen gas and the derivative of the molecule of interest. In some embodiments, the parahydrogenation reactions hydrogenates at least one double bond or triple bond of the derivative of the molecule of interest, thereby forming the molecule of interest and transferring spin order from the parahydrogen gas to the molecule of interest via a PHIP interaction as described herein.

In some embodiments, the parahydrogen gas is mixed with the derivative of the molecule of interest in the presence of any hydrogenation catalyst described herein. In some embodiments, such mixing induces a parahydrogenation reaction between the parahydrogen gas and the derivative of the molecule of interest. In some embodiments, the parahydrogenation reaction hydrogenates at least one double bond or triple bond of the derivative of the molecule of interest and forms a parahydrogenated derivative of the molecule of interest. In some embodiments, the first solution containing the parahydrogenated derivative of the molecule of interest is mixed with any hydrolysis agent described herein. In some embodiments, the hydrolysis agent hydrolyzes the parahydrogenated derivative of the biomolecule of interest and thereby form a hydrolyzed sidearm and the molecule of interest via a PHIP-SAH interaction as described herein.

In some embodiments, the first solution is purified at step 430. In some embodiments, the first solution is purified using any purification method described herein. For instance, in some embodiments, purifying the first solution comprises mixing the first solution with a second solution to thereby form a third solution containing the molecule of interest, as described herein. In some embodiments, the third solution comprises a reduced concentration of contaminants compared with the first solution, as described herein. In some embodiments, purifying the first solution comprises performing a precipitation reaction on the first solution to thereby form a precipitate of the molecule of interest and mixing the precipitate of the molecule of interest with a second solution to thereby form a third solution containing the molecule of interest, as described herein.

Systems for Producing Parahydrogen Gas from Liquid Parahydrogen

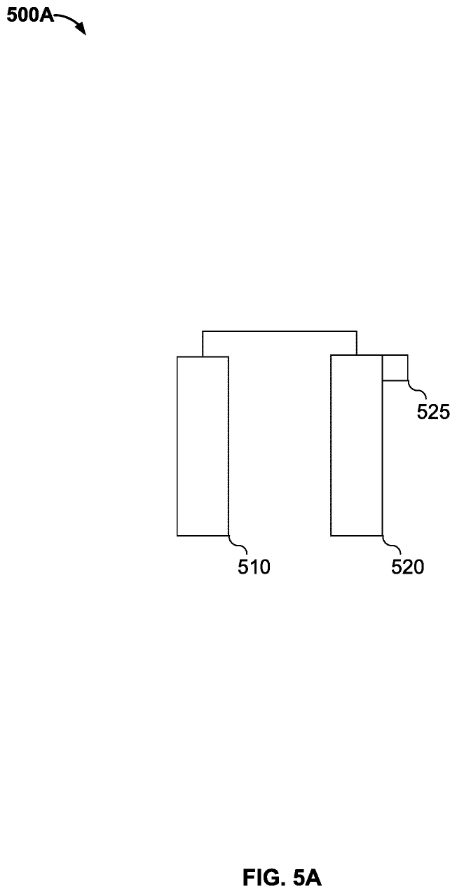

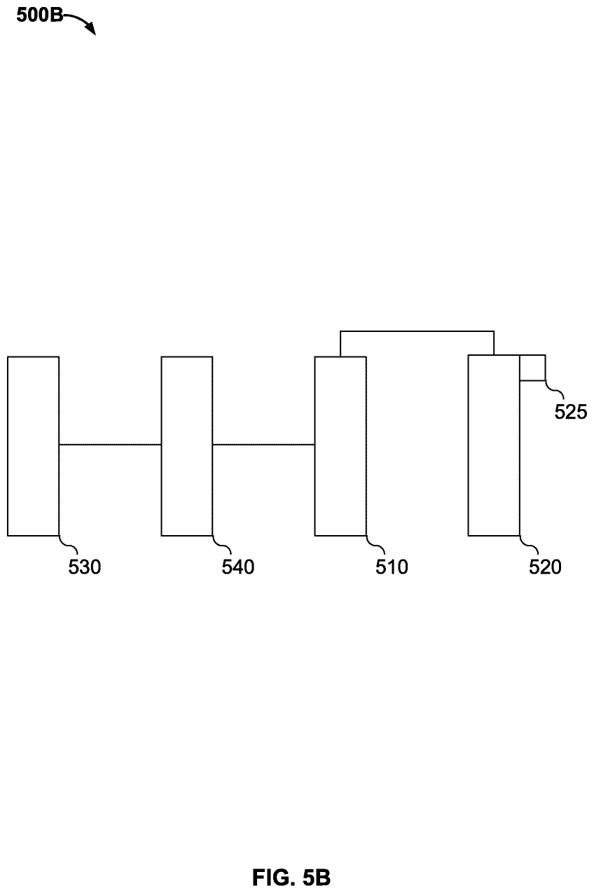

FIG. 5A depicts a second exemplary system 500A for providing parahydrogen gas for use in a PHIP, PHIP-SAH, SABRE, or PHIPNOESYS application, in accordance with disclosed embodiments. In the example shown, the system 500A comprises a cryogenic container 510. In some embodiments, the cryogenic container 510 is configured to contain liquid hydrogen therein. In some embodiments, the cryogenic container 510 contains liquid hydrogen therein. In some embodiments, the liquid hydrogen comprises at least about 50 mol %, 55 mol %, 60 mol %, 65 mol %, 70 mol %, 75 mol %, 80 mol %, 85 mol %, 90 mol %, 95 mol %, or more liquid parahydrogen. In some embodiments, the liquid hydrogen comprises at most about 95 mol %, 90 mol %, 85 mol %, 80 mol %, 75 mol %, 70 mol %, 65 mol %, 60 mol %, 55 mol %, 50 mol %, or less liquid parahydrogen. In some embodiments, the liquid hydrogen comprises an amount of liquid parahydrogen that is within a range defined by any two of the preceding values.

In some embodiments, the cryogenic container 510 comprises a volume of at least about 1 liter (L), 2 L, 3 L, 4 L, 5 L, 6 L, 7 L, 8 L, 9 L, 10 L, 20 L, 30 L, 40 L, 50 L, 60 L, 70 L, 80 L, 90 L, 100 L, 200 L, 300 L, 400 L, 500 L, 600 L, 700 L, 800 L, 900 L, 1,000 L, or more. In some embodiments, the cryogenic container 510 comprises a volume of at most about 1,000 L, 900 L, 800 L, 700 L, 600 L, 500 L, 400 L, 300 L, 200 L, 100 L, 90 L, 80 L, 70 L, 60 L, 50 L, 40 L, 30 L, 20 L, 10 L, 9 L, 8 L, 7 L, 6 L, 5 L, 4 L, 3 L, 2 L, 1 L, or less. In some embodiments, the cryogenic container 510 comprises a volume that is within a range defined by any two of the preceding values.

In some embodiments, the cryogenic container 510 comprises a first vessel and a second vessel. In some embodiments, the first vessel is configured to contain the liquid hydrogen therein. In some embodiments, the first vessel is located within the second vessel. In some embodiments, the second vessel is configured to reduce heat transfer from the surrounding environment to the first vessel and the liquid hydrogen contained therein. In some embodiments, the second vessel is configured to be evacuated (i.e., to be subjected to low, medium, high, or ultra-high vacuum conditions) or is evacuated. In some embodiments, evacuating the second vessel reduces convective and conductive heat transfer from the surrounding environment to the first vessel and the liquid hydrogen contained therein. In some embodiments, the second vessel is not configured to be evacuated or is not evacuated. In some embodiments, the cryogenic container 510 contains one or more radiation shields located between the first vessel and the second vessel. In some embodiments, the one or more radiation shields reduce radiative heat transfer from the surrounding environment to the first vessel and the liquid hydrogen contained therein.

In some embodiments, the cryogenic container 510 comprises a first vessel, a second vessel, and a third vessel. In some embodiments, the first vessel is configured to contain the liquid hydrogen therein. In some embodiments, the first vessel is located within the second vessel. In some embodiments, the second vessel is located within the third vessel. In some embodiments, the second vessel and the third vessel are configured to reduce heat transfer from the surrounding environment to the first vessel and the liquid hydrogen contained therein. In some embodiments, the second vessel is configured to be evacuated (i.e., to be subjected to low, medium, high, or ultra-high vacuum conditions) or is evacuated. In some embodiments, evacuating the second vessel reduces convective and conductive heat transfer from the surrounding environment to the first vessel and the liquid hydrogen contained therein. In some embodiments, the second vessel is not configured to be evacuated or is not evacuated. In some embodiments, the cryogenic container 510 contains one or more radiation shields located between the first vessel and the second vessel. In some embodiments, the one or more radiation shields reduce radiative heat transfer from the surrounding environment to the first vessel and the liquid hydrogen contained therein. In some embodiments, the third vessel is configured to contain a cryogenic liquid (e.g., liquid nitrogen) therein. In some embodiments, containing a cryogenic liquid within the third vessel reduces heat transfer from the surrounding environment to the first vessel and the liquid hydrogen contained therein. In some embodiments, the cryogenic container 510 contains one or more radiation shields located between the first vessel and the third vessel. In some embodiments, the one or more radiation shields reduce radiative heat transfer from the surrounding environment to the first vessel and the liquid hydrogen contained therein.

In some embodiments, the cryogenic container 510 comprises a first vessel, a second vessel, a third vessel, and a fourth vessel. In some embodiments, the first vessel is configured to contain the liquid hydrogen therein. In some embodiments, the first vessel is located within the second vessel. In some embodiments, the second vessel is located within the third vessel. In some embodiments, the third vessel is located within the fourth vessel. In some embodiments, the second vessel, the third vessel, and the fourth vessel are configured to reduce heat transfer from the surrounding environment to the first vessel and the liquid hydrogen contained therein. In some embodiments, the second vessel is configured to be evacuated (i.e., to be subjected to low, medium, high, or ultra-high vacuum conditions) or is evacuated. In some embodiments, evacuating the second vessel reduces convective and conductive heat transfer from the surrounding environment to the first vessel and the liquid hydrogen contained therein. In some embodiments, the second vessel is not configured to be evacuated or is not evacuated. In some embodiments, the cryogenic container 510 contains one or more radiation shields located between the first vessel and the second vessel. In some embodiments, the one or more radiation shields reduce radiative heat transfer from the surrounding environment to the first vessel and the liquid hydrogen contained therein. In some embodiments, the third vessel is configured to contain a cryogenic liquid (e.g., liquid nitrogen) therein. In some embodiments, containing a cryogenic liquid within the third vessel reduces heat transfer from the surrounding environment to the first vessel and the liquid hydrogen contained therein. In some embodiments, the cryogenic container 510 contains one or more radiation shields located between the first vessel and the third vessel. In some embodiments, the one or more radiation shields reduce radiative heat transfer from the surrounding environment to the first vessel and the liquid hydrogen contained therein. In some embodiments, the fourth vessel is configured to be evacuated (i.e., to be subjected to low, medium, high, or ultra-high vacuum conditions) or is evacuated. In some embodiments, evacuating the fourth vessel reduces convective and conductive heat transfer from the surrounding environment to the first vessel and the liquid hydrogen contained therein. In some embodiments, the fourth vessel is not configured to be evacuated or is not evacuated. some embodiments, the cryogenic container 510 contains one or more radiation shields located between the first vessel and the fourth vessel. In some embodiments, the one or more radiation shields reduce radiative heat transfer from the surrounding environment to the first vessel and the liquid hydrogen contained therein.

In some embodiments, the system 500A comprises a chamber 520. In some embodiments, the chamber 520 is fluidically coupled to the cryogenic container 510. In some embodiments, the chamber 520 is configured to receive the liquid hydrogen from the cryogenic container 510. In some embodiments, the chamber 520 is configured to boil the received liquid hydrogen to thereby form a first hydrogen gas. In some embodiments, the chamber 520 comprises a heater configured to boil the received liquid hydrogen to thereby form the first hydrogen gas. In some embodiments, the first hydrogen gas comprises at least about 50 mol %, 55 mol %, 60 mol %, 65 mol %, 70 mol %, 75 mol %, 80 mol %, 85 mol %, 90 mol %, 95 mol %, or more parahydrogen gas. In some embodiments, the first hydrogen gas comprises at most about 95 mol %, 90 mol %, 85 mol %, 80 mol %, 75 mol %, 70 mol %, 65 mol %, 60 mol %, 55 mol %, 50 mol %, or less parahydrogen gas. In some embodiments, the first hydrogen gas comprises an amount of parahydrogen gas that is within a range defined by any two of the preceding values.

In some embodiments, the system 500A comprises a port 525. In some embodiments, the port 525 is fluidically coupled to the chamber 520. In some embodiments, the port 525 is configured to fluidically couple the chamber 520 to a gas cylinder or to a fluid pump (not shown in FIG. 5A). In some embodiments, the gas cylinder or the fluid pump are configured to deliver the first hydrogen gas to a solution. In some embodiments, the solution comprises a target molecule (also referred to herein as a target compound or molecule of interest) or precursor to a target molecule. In some embodiments, the target molecule or precursor to the target molecule comprises a molecule to be used in a PHIP, PHIP-SAH, SABRE, or PHIPNOESYS application. In some embodiments, the target molecule comprises any biorelevant imaging agent described herein. In some embodiments, the solution further comprises a catalyst, such as a hydrogenation catalyst.

In the example shown in FIG. 5A, the system 500A is configured to generate a relatively high concentration of liquid parahydrogen in the liquid hydrogen. In some embodiments, the system 500A is configured to generate a relatively high concentration of liquid parahydrogen while the hydrogen is in the liquid phase. For example, in some embodiments, the cryogenic container 510 is configured to contain a first parahydrogen conversion catalyst therein. In some embodiments, the first parahydrogen conversion catalyst is configured to convert liquid orthohydrogen contained in the liquid hydrogen into liquid parahydrogen. In this manner, a relatively high concentration of liquid parahydrogen may be directly generated in the liquid hydrogen.

FIG. 5B depicts a third exemplary system 500B for providing parahydrogen gas for use in a PHIP, PHIP-SAH, SABRE, or PHIPNOESYS application, in accordance with disclosed embodiments. In the example shown, the system 500B comprises a cryogenic container 510. In some embodiments, the cryogenic container 510 comprises any cryogenic container described herein with respect to FIG. 5A.

In some embodiments, the system 500B comprises a chamber 520. In some embodiments, the chamber 520 comprises any chamber described herein with respect to FIG. 5A.

In the example shown in FIG. 5B, the system 500B is configured to generate a relatively high concentration of liquid parahydrogen by first generating a relatively high concentration of gaseous parahydrogen while the hydrogen is in the gas phase, followed by condensation of the gaseous hydrogen. For example, in some embodiments, the system 500B optionally further comprises a gas-tight container 530. In some embodiments, the gas-tight container 530 is configured to contain a second hydrogen gas therein. In some embodiments, the gas-tight container 530 is configured to contain a second parahydrogen conversion catalyst therein. In some embodiments, the second parahydrogen conversion catalyst is configured to convert gaseous orthohydrogen in the second hydrogen gas into gaseous parahydrogen. Thus, in some embodiments, the gas-tight container 530 is configured to generate a third hydrogen gas comprising a relatively high amount of gaseous parahydrogen therein (such as at least about 50 mol %, 55 mol %, 60 mol %, 65 mol %, 70 mol %, 75 mol %, 80 mol %, 85 mol %, 90 mol %, 95 mol %, or more parahydrogen, at most about 95 mol %, 90 mol %, 85 mol %, 80 mol %, 75 mol %, 70 mol %, 65 mol %, 60 mol %, 55 mol %, 50 mol %, or less parahydrogen, or an amount of parahydrogen that is within a range defined by any two of the preceding values).

In some embodiments, the system 500B further optionally comprises a condenser 540. In some embodiments, the condenser 540 is fluidically coupled to the gas-tight container 530. In some embodiments, the condenser 540 is configured to receive the third hydrogen gas from the gas-tight container 530, to condense the third hydrogen gas, and to generate the liquid hydrogen therefrom. In some embodiments, the condenser 540 is fluidically coupled to the cryogenic container 510 and configured to deliver the liquid hydrogen to the cryogenic container 510.

In some embodiments, the first parahydrogen conversion catalyst (described herein with respect to FIG. 5A) or the second parahydrogen conversion catalyst (described herein with respect to FIG. 5B) comprises a material configured to: (1) adsorb the liquid or gaseous orthohydrogen, respectively, (2) split the liquid or gaseous orthohydrogen, respectively, and (3) release the liquid or gaseous orthohydrogen, respectively. In some embodiments, the first or second parahydrogen conversion catalyst comprises a paramagnetic material. In some embodiments, the orthohydrogen comprises two hydrogen spins and the first or second parahydrogen conversion catalyst breaks a symmetry between the two hydrogen spins to thereby convert to the orthohydrogen to parahydrogen.

In some embodiments, the first or second parahydrogen conversion catalyst comprises gadolinium oxide, crude ceric oxide, neodymium oxide, FeCl₂ on silica gel, paramagnetic Fe₂O₃ on porous glass, about 2% paramagnetic Fe₂O₃ on porous glass, paramagnetic Fe₂O₃ on Florex, about 15% paramagnetic Fe₂O₃ on Florex, ferric ammonium sulfate, magnetite, Fe₃O₄, Cr₂O₃ on alumina, paramagnetic Fe₂O₃ and Cr₂O₃ on alumina, about 15% paramagnetic Fe₂O₃ and about 9.3% Cr₂O₃ on alumina, Ni and thoria on alumina, about 5.3% Ni and about 0.24% thoria on alumina, MnO₂ on silica gel, about 18% MnO₂ on silica gel, Ni on alumina, about 0.5% Ni on alumina, hydrous manganese dioxide, hydrous ferric oxide, hydrated iron oxide, or any possible combination of the preceding materials.

Methods for Producing Parahydrogen Gas from Liquid Parahydrogen

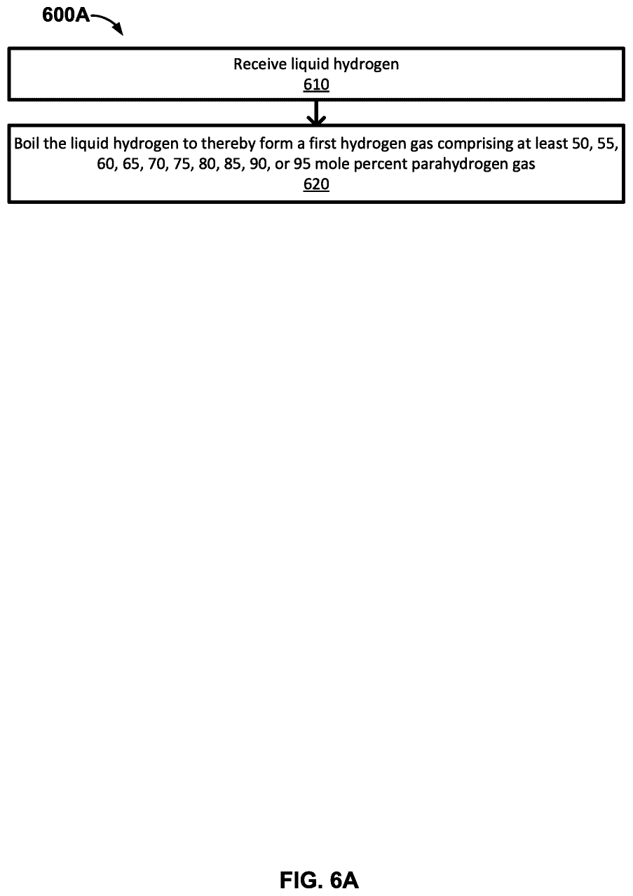

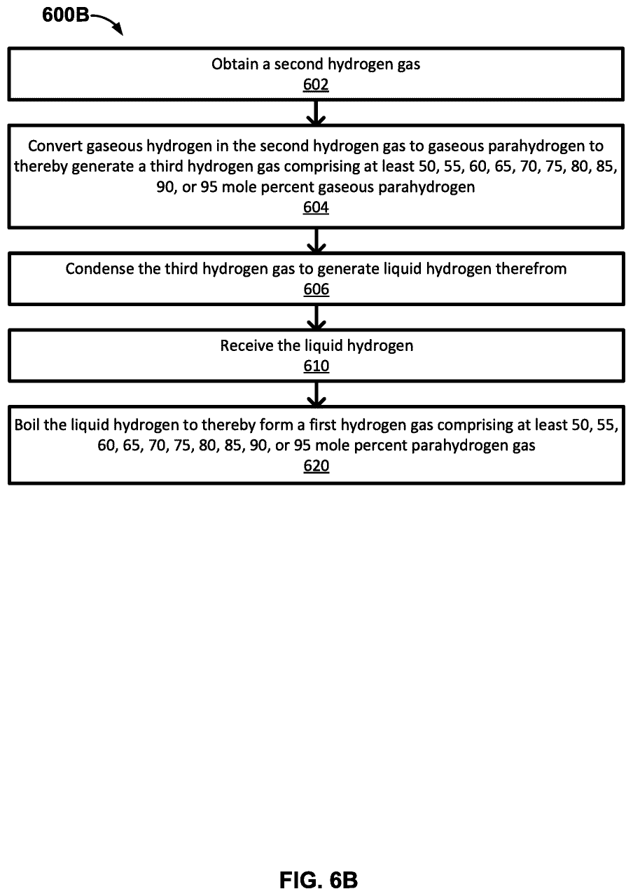

FIG. 6A depicts a second exemplary method 600A for providing parahydrogen gas for use in a PHIP, PHIP-SAH, SABRE, or PHIPNOESYS NMR or MRI application, in accordance with disclosed embodiments. In some embodiments, method 600A is performed using system 500A described herein with respect to FIG. 5A.

At step 610, liquid hydrogen is received. In some embodiments, the liquid hydrogen comprises any liquid hydrogen described herein with respect to FIG. 5A. For instance, in some embodiments, the liquid hydrogen comprises at least about 50 mol %, 55 mol %, 60 mol %, 65 mol %, 70 mol %, 75 mol %, 80 mol %, 85 mol %, 90 mol %, 95 mol %, or more liquid parahydrogen. In some embodiments, the liquid hydrogen comprises at most about 95 mol %, 90 mol %, 85 mol %, 80 mol %, 75 mol %, 70 mol %, 65 mol %, 60 mol %, 55 mol %, 50 mol %, or less liquid parahydrogen. In some embodiments, the liquid hydrogen comprises an amount of liquid parahydrogen that is within a range defined by any two of the preceding values.

In some embodiments, the liquid hydrogen is received in any cryogenic container described herein with respect to FIG. 5A. For instance, in some embodiments, the liquid hydrogen is received in a cryogenic container comprising a volume of at least about 1 L, 2 L, 3 L, 4 L, 5 L, 6 L, 7 L, 8 L, 9 L, 10 L, 20 L, 30 L, 40 L, 50 L, 60 L, 70 L, 80 L, 90 L, 100 L, 200 L, 300 L, 400 L, 500 L, 600 L, 700 L, 800 L, 900 L, 1,000 L, or more, a volume of at most about 1,000 L, 900 L, 800 L, 700 L, 600 L, 500 L, 400 L, 300 L, 200 L, 100 L, 90 L, 80 L, 70 L, 60 L, 50 L, 40 L, 30 L, 20 L, 10 L, 9 L, 8 L, 7 L, 6 L, 5 L, 4 L, 3 L, 2 L, 1 L, or less, or a volume that is within a range defined by any two of the preceding values.

At step 620, the liquid hydrogen is boiled. In some embodiments, boiling the liquid hydrogen forms a first hydrogen gas. In some embodiments, the first hydrogen gas comprises any first hydrogen gas described herein with respect to FIG. 5A. For instance, in some embodiments, the first hydrogen gas comprises at least about 50 mol %, 55 mol %, 60 mol %, 65 mol %, 70 mol %, 75 mol %, 80 mol %, 85 mol %, 90 mol %, 95 mol %, or more parahydrogen gas, at most about 95 mol %, 90 mol %, 85 mol %, 80 mol %, 75 mol %, 70 mol %, 65 mol %, 60 mol %, 55 mol %, 50 mol %, or less parahydrogen gas, or an amount of parahydrogen gas that is within a range defined by any two of the preceding values.

In some embodiments, the method 600A further comprises using a first parahydrogen conversion catalyst to convert liquid orthohydrogen to liquid parahydrogen. In some embodiments, the first parahydrogen conversion catalyst comprises any first parahydrogen conversion catalyst described herein with respect to FIG. 5A.

In some embodiments, the method 600A further comprises delivering the first hydrogen gas to a solution. In some embodiments, the solution comprises any solution described herein with respect to FIG. 5A. In some embodiments, the solution comprises any target molecule or any precursor to any target molecule described herein with respect to FIG. 5A. In some embodiments, the solution comprises any catalyst described herein with respect to FIG. 5A. In some embodiments, the method 600A further comprises using the first hydrogen gas to hydrogenate a PHIP, PHIP-SAH, or PHIPNOESYS precursor to their generate the target molecule. In some embodiments, the method 600A further comprises delivering the target molecule to a subject or to a sample. In some embodiments, the method 600A further comprises obtaining an NMR spectrum or MRI image of the subject sample in response to the target molecule.

FIG. 6B depicts a third exemplary method 600B for providing parahydrogen gas for use in a PHIP, PHIP-SAH, SABRE, or PHIPNOESYS NMR or MRI application, in accordance with disclosed embodiments. In some embodiments, method 600B is performed using system 500B described herein with respect to FIG. 5B.

At step 602, second hydrogen gas is obtained. In some embodiments, the second hydrogen gas comprises any second hydrogen gas described herein with respect to FIG. 5B.

At step 604, gaseous orthohydrogen in the second hydrogen gas is converted to gas parahydrogen to thereby generate a third hydrogen gas. In some embodiments, the third hydrogen gas comprises any third hydrogen gas described herein with respect to FIG. 5B. For instance, in some embodiments, the third hydrogen gas comprises at least about 50 mol %, 55 mol %, 60 mol %, 65 mol %, 70 mol %, 75 mol %, 80 mol %, 85 mol %, 90 mol %, 95 mol %, or more gaseous parahydrogen, at most about 95 mol %, 90 mol %, 85 mol %, 80 mol %, 75 mol %, 70 mol %, 65 mol %, 60 mol %, 55 mol %, 50 mol %, or less gaseous parahydrogen, or an amount of gaseous parahydrogen that is within a range defined by any two of the preceding values.

In some embodiments, the method 600B further comprises using a second parahydrogen conversion catalyst to convert gaseous orthohydrogen to gaseous parahydrogen. In some embodiments, the second parahydrogen conversion catalyst comprises any second parahydrogen conversion catalyst described herein with respect to FIG. 5B.

At step 606, the third hydrogen gas is condensed to thereby generate liquid hydrogen.

At step 610, the liquid hydrogen is received. In some embodiments, the liquid hydrogen comprises any liquid hydrogen described herein with respect to FIG. 5B. For instance, in some embodiments, the liquid hydrogen comprises at least about 50 mol %, 55 mol %, 60 mol %, 65 mol %, 70 mol %, 75 mol %, 80 mol %, 85 mol %, 90 mol %, 95 mol %, or more liquid parahydrogen. In some embodiments, the liquid hydrogen comprises at most about 95 mol %, 90 mol %, 85 mol %, 80 mol %, 75 mol %, 70 mol %, 65 mol %, 60 mol %, 55 mol %, 50 mol %, or less liquid parahydrogen. In some embodiments, the liquid hydrogen comprises an amount of liquid parahydrogen that is within a range defined by any two of the preceding values.

In some embodiments, the liquid hydrogen is received in any cryogenic container described herein with respect to FIG. 5B. For instance, in some embodiments, the liquid hydrogen is received in a cryogenic container comprising a volume of at least about 1 L, 2 L, 3 L, 4 L, 5 L, 6 L, 7 L, 8 L, 9 L, 10 L, 20 L, 30 L, 40 L, 50 L, 60 L, 70 L, 80 L, 90 L, 100 L, 200 L, 300 L, 400 L, 500 L, 600 L, 700 L, 800 L, 900 L, 1,000 L, or more, a volume of at most about 1,000 L, 900 L, 800 L, 700 L, 600 L, 500 L, 400 L, 300 L, 200 L, 100 L, 90 L, 80 L, 70 L, 60 L, 50 L, 40 L, 30 L, 20 L, 10 L, 9 L, 8 L, 7 L, 6 L, 5 L, 4 L, 3 L, 2 L, 1 L, or less, or a volume that is within a range defined by any two of the preceding values.

At step 620, the liquid hydrogen is boiled. In some embodiments, boiling the liquid hydrogen forms a first hydrogen gas. In some embodiments, the first hydrogen gas comprises any first hydrogen gas described herein with respect to FIG. 5B. For instance, in some embodiments, the first hydrogen gas comprises at least about 50 mol %, 55 mol %, 60 mol %, 65 mol %, 70 mol %, 75 mol %, 80 mol %, 85 mol %, 90 mol %, 95 mol %, or more parahydrogen gas, at most about 95 mol %, 90 mol %, 85 mol %, 80 mol %, 75 mol %, 70 mol %, 65 mol %, 60 mol %, 55 mol %, 50 mol %, or less parahydrogen gas, or an amount of parahydrogen gas that is within a range defined by any two of the preceding values.

In some embodiments, the method 600B further comprises delivering the first hydrogen gas to a solution. In some embodiments, the solution comprises any solution described herein with respect to FIG. 5B. In some embodiments, the solution comprises any target molecule or any precursor to any target molecule described herein with respect to FIG. 5B. In some embodiments, the solution comprises any catalyst described herein with respect to FIG. 5B. In some embodiments, the method 600B further comprises using the first hydrogen gas to hydrogenate a PHIP, PHIP-SAH, or PHIPNOESYS precursor to their generate the target molecule. In some embodiments, the method 600B further comprises delivering the target molecule to a subject or to a sample. In some embodiments, the method 600B further comprises obtaining an NMR spectrum or MRI image of the subject sample in response to the target molecule.

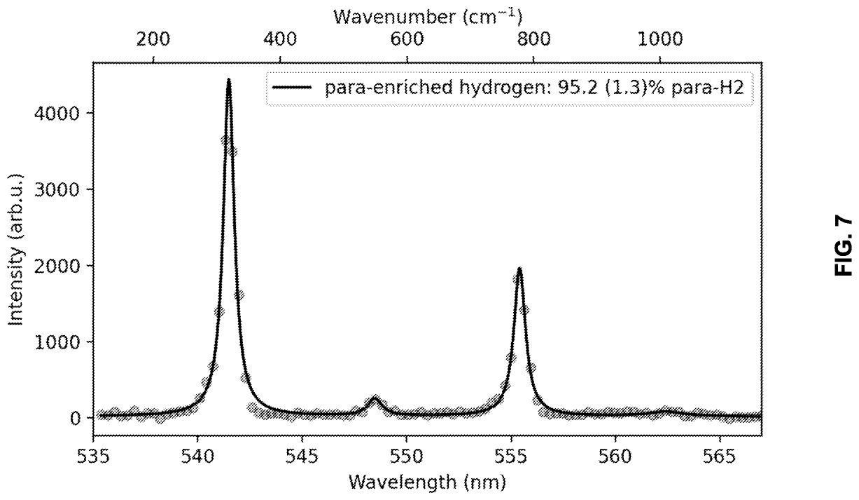

FIG. 7 depicts an exemplary Raman spectrum of a hydrogen gas mixture containing more than 90% parahydrogen generated from liquid hydrogen, in accordance with disclosed embodiments. Liquid hydrogen was exposed to a parahydrogen conversion catalyst to convert liquid orthohydrogen to liquid parahydrogen. The liquid hydrogen was the boiled to form gaseous hydrogen. The gaseous hydrogen was analyzed using a homebuilt Raman spectrometer. The Raman spectrometer used a laser excitation at approximately 532 nanometers (nm) and 100 milliwatts (mW) of laser power. Raman peaks corresponding to parahydrogen occurred at approximately 542 nm. Raman peaks corresponding to orthohydrogen occurred at approximately 549 nm and 556 nm. The areas under the respective peaks were calculated to determine the concentrations of parahydrogen and orthohydrogen in the hydrogen gas. To retrieve the areas of the peaks, the peaks were fit to Lorentzian functions. During calculations, the anisotropy of the polarizability tensor was taken into account. Using this method, the hydrogen gas was calculated to contain 95.2% parahydrogen. Thus, preparing parahydrogen in the liquid state and boiling the liquid is a viable method for producing hydrogen gas containing a high concentration of parahydrogen.

### Biorelevant Imaging Agents

The disclosed embodiments include systems and methods for producing and utilizing biorelevant imaging agents with clinically relevant polarizations, concentrations, volumes, or purities. In some embodiments, the method is for preparing an NMR material (also referred to herein as a “molecule of interest”). In some embodiments, the NMR material is suitable for use in NMR or MRI operations. In some embodiments, the NMR material increases NMR or MRI signal and signal-to-noise ratio (SNR). In some embodiments, the NMR material is suitable for use in solution NMR spectroscopy. In some embodiments, the NMR material is a chemical compound. In some embodiments, the NMR material is a metabolite (e.g., a molecule with a biological relevance such as an amino acid, a saccharide, a derivative thereof, or the like), such as a metabolite suitable for use in an NMR metabolomics application. In some embodiments, the NMR material is suitable for in-vitro probing of the metabolism of a cell culture or other biological tissue. In some embodiments, the NMR material is used in an NMR probe to investigate a transient effect in which high signal enhancement due to hyperpolarization is needed, such as proton exchange between water and biomolecules. In some embodiments, the NMR material is a small molecule or metabolite suitable for injection into a cell, tissue or organism for detection in an MRI scan. In some embodiments, the NMR material is introduced into a chamber for further analysis by NMR or MRI operations. In some embodiments, the NMR material is enriched with one or more deuterium (²H) or carbon-13 (¹³C) atoms.

Consistent with disclosed embodiments, NMR material can include biorelevant imaging agents. In some embodiments, the biorelevant imaging agent can be suitable for use in NMR or MRI operations. In some embodiments, the biorelevant imaging agent may increase NMR or MRI signal or signal-to-noise ratio (SNR). In some embodiments, the biorelevant imaging agent can be suitable for use in solution NMR spectroscopy. In some embodiments, the biorelevant imaging agent may be a metabolite (e.g., a molecule with a biological relevance such as an amino acid, a saccharide, a derivative thereof, or the like), such as a metabolite suitable for use in an NMR metabolomics application. In some embodiments the biorelevant imaging agent is used for perfusion imaging or contrast enhanced imaging in MRI scans. In some embodiments, the biorelevant imaging agent is suitable for in-vitro probing of the metabolism of a cell culture or other biological tissue. In some embodiments, the biorelevant imaging agent is used for in-vitro probing of the metabolism of a cell culture or other biological tissue. In some embodiments, the biorelevant imaging agent is used in an NMR probe to investigate a transient effect in which high signal enhancement due to hyperpolarization is needed, such as proton exchange between water and biomolecules. In some embodiments, the biorelevant imaging agent is a small molecule or metabolite suitable for injection into a cell, tissue or organism for detection in an MRI scan. In some embodiments, the biorelevant imaging agent is introduced into a chamber for further analysis by NMR or MRI operations. In some embodiments, the biorelevant imaging agent is enriched with one or more ²H or ¹³C atoms.

In some embodiments, the biorelevant imaging agent comprises pyruvate, lactate, alpha-ketoglutarate, bicarbonate, fumarate, urea, dehydroascorbate, glutamate, glutamine, acetate, dihydroxyacetone, acetoacetate, glucose, ascorbate, zymonate, alanine, fructose, imidazole, nicotinamide, nitroimidazole, pyrazinamide, isoniazid, a conjugate acid of any of the foregoing, natural and unnatural amino acids, esters thereof, or ²H, ¹³C, or nitrogen-15 (¹⁵N) enriched versions of any of the foregoing. In some embodiments, the biorelevant imaging agent comprises pyruvate, lactate, alpha-ketoglutarate. In some embodiments, the biorelevant imaging agent comprises pyruvate. In some embodiments, the biorelevant imaging agent comprises lactate. In some embodiments, the biorelevant imaging agent comprises alpha-ketoglutarate (e.g., ethyl alpha-ketoglutarate).

In some embodiments, the biorelevant imaging agent comprises at least one non-hydrogen nuclear spin. In some embodiments, the non-hydrogen nuclear comprises at least one spin-½ atom. In some embodiments, the non-hydrogen nuclear spin comprises ¹³C or ¹⁵N. In some embodiments, the biorelevant imaging agent is at least partially isotopically labeled with the non-hydrogen nuclear spin. In some embodiments, the biorelevant imaging agent is at least partially enriched with the non-hydrogen nuclear spin when compared to an analog of the biorelevant imaging agent that features the non-hydrogen nuclear spin at its natural abundance. In some embodiments, the biorelevant imaging agent is enriched to feature the non-hydrogen nuclear spin at an abundance of at least about 1%, 2%, 3%, 4%, 5%, 6%, 7%, 8%, 9%, 10%, 15%, 20%, 25%, 30%, 35%, 40%, 45%, 50%, 55%, 60%, 65%, 70%, 75%, 80%, 85%, 90%, 91%, 92%, 93%, 94%, 95%, 96%, 97%, 98%, 99%, or more, at most about 99%, 98%, 97%, 96%, 95%, 94%, 93%, 92%, 91%, 90%, 85%, 80%, 75%, 70%, 65%, 60%, 55%, 50%, 45%, 40%, 35%, 30%, 25%, 20%, 15%, 10%, 9%, 8%, 7%, 6%, 5%, 4%, 3%, 2%, 1%, or less, or an abundance that is within a range defined by any two of the preceding values.

In some embodiments, the non-hydrogen nuclear spin replaces an NMR-inactive (i.e., spin-0) nucleus (e.g., ¹²C or a quadrupolar (i.e., spin>½) nucleus (e.g., nitrogen-14, ¹⁴N) of the analog of the biorelevant imaging agent that features the non-hydrogen nuclear spin at its natural abundance. For example, an analog of pyruvate that features ¹³C at its natural abundance may include about 98.9% ¹²C and about 1.1% ¹³C at either C* in the structure H₃C—C*(═O)—C*OOH. As a biorelevant imaging agent, pyruvate may instead be isotopically enriched with ¹³C such that one or both C* comprises ¹³C at any abundance described herein. As used herein, *C and C* describe a carbon that can be either a ¹²C or ¹³C carbon isotope. As another example, an analog of urea that features ¹⁵N at its natural abundance may include about 99.6% ¹⁴N and about 0.4% ¹⁵N at either N* in the structure H₂N*—C(═O)—*NH₂. As a biorelevant imaging agent, urea may instead be isotopically enriched with ¹⁵N such that one or both N* comprises ¹⁵N at any abundance described herein. As used herein, *N and N* describe a nitrogen that can be either a ¹⁴N or ¹⁵N nitrogen isotope.

Transportation of Liquid and/or Gaseous Parahydrogen

Parahydrogen can be generated at a first location (e.g., in a gas cylinder described herein or in a cryogenic container described herein) and subsequently transported to a second location for use. In some embodiments, the first location is a physical location such as a room, a lab, a particular warehouse, hospital, automobile, truck, or other location where the parahydrogen is generated. In some embodiments, the gas cylinder or the cryogenic container is cooled to temperatures below room temperature before, during, or after transport. For instance, in some embodiments, the gas cylinder or the cryogenic container is cooled to a temperature below about 200 K, 190 K, 180 K, 170 K, 160 K, 150 K, 140 K, 130 K, 120 K, 110 K, 100 K, 90 K, 80 K, 70 K, 60 K, 50 K, or less, a temperature above about 50 K, 60 K, 70 K, 80 K, 90 K, 100 K, 110 K, 120 K, 130 K, 140 K, 150 K, 160 K, 170 K, 180 K, 190 K, 200 K, or more, or a temperature that is within a range defined by any two of the preceding values. In some embodiments, the gas cylinder or the cryogenic container is cooled using ice, dry ice, or liquid nitrogen. In some embodiments, cooling the gas cylinder or the cryogenic container increases the lifetime of the gaseous or liquid parahydrogen contained therein.

The generated parahydrogen may be transported in the gas cylinder or the cryogenic container to a second location. The second location may be different from the first location. The gas cylinder or the cryogenic container may be transported by vehicle or persons. Transporting the parahydrogen may involve moving the gas cylinder or the cryogenic container within the same location, such as from one part of a room to another part of the room. Transporting the gas cylinder or the cryogenic container may involve moving the gas cylinder or the cryogenic container from one room in a building to a different room in the same building or to a nearby building. Transporting the gas cylinder or the cryogenic container may involve moving the gas cylinder or the cryogenic container to a different location in another part of the same city, a different city, a different state, a different province, a different territory, a different country, or even a different continent. Transporting the gas cylinder or the cryogenic container may involve bringing the gas cylinder or the cryogenic container into the vicinity of an NMR device or an MRI device. Transporting the gas cylinder or the cryogenic container may involve packaging or shipping the gas cylinder or the cryogenic container in suitable containers.

### Precipitation

In various embodiments, the molecule of interest can be crystalized or precipitated out of the solutions described herein. The disclosed embodiments are not limited to any particular method of inducing such precipitation. For example, such precipitation can be induced by through a change in temperature or pH, application of an electromagnetic stimulus (e.g., optical radiation, such as ultraviolet radiation or optical radiation at another suitable wavelength or wavelengths), mechanical stimulus (e.g., ultrasound, agitation, or another suitable mechanical stimulus), addition of another solute or solvent to the solution, or another suitable method, or any combination thereof. In some embodiments, following precipitation, the molecule of interest can be separated from the solution (e.g., using a filter, or another suitable method). In some embodiments, the molecule of interest may then be combined or redissolved into another solution. This solution may have desirable characteristics (e.g., biocompatibility, concentration, volume, temperature, pH, polarity, or other relevant characteristics, or any combination thereof) for the intended NMR or MRI application.

### Use of Molecules of Interest

In some embodiments, at least a portion of the molecule of interest can be injected into a subject or patient for use in an MRI experiment. In various embodiments, at least a portion of the molecule of interest can be used in NMR spectroscopy. At least one NMR or MRI pulse sequence can be applied to the molecule of interest.

The foregoing description has been presented for purposes of illustration. It is not exhaustive and is not limited to precise forms or embodiments disclosed. Modifications and adaptations of the embodiments will be apparent from consideration of the specification and practice of the disclosed embodiments. For example, the described implementations include hardware, but systems and methods consistent with the present disclosure can be implemented with hardware and software. In addition, while certain components have been described as being coupled to one another, such components may be integrated with one another or distributed in any suitable fashion.

Moreover, while illustrative embodiments have been described herein, the scope includes any and all embodiments having equivalent elements, modifications, omissions, combinations (e.g., of aspects across various embodiments), adaptations or alterations based on the present disclosure. The elements in the claims are to be interpreted broadly based on the language employed in the claims and not limited to examples described in the present specification or during the prosecution of the application, which examples are to be construed as nonexclusive. Further, the steps of the disclosed methods can be modified in any manner, including reordering steps or inserting or deleting steps.

The features and advantages of the disclosure are apparent from the detailed specification, and thus, it is intended that the appended claims cover all systems and methods falling within the true spirit and scope of the disclosure. As used herein, the indefinite articles “a” and “an” mean “one or more.” Similarly, the use of a plural term does not necessarily denote a plurality unless it is unambiguous in the given context. Further, since numerous modifications and variations will readily occur from studying the present disclosure, it is not desired to limit the disclosure to the exact construction and operation illustrated and described, and accordingly, all suitable modifications and equivalents may be resorted to, falling within the scope of the disclosure.

As used herein, unless specifically stated otherwise, the term “or” encompasses all possible combinations, both conjunctive and disjunctive, except where infeasible. For example, if it is stated that a component may include A or B, then, unless specifically stated otherwise or infeasible, the component may include A alone, or B alone, or A and B. As a second example, if it is stated that a component may include A, B, or C, then, unless specifically stated otherwise or infeasible, the component may include A alone, or B alone, or C alone, or A and B, or A and C, or B and C, or A and B and C.

### RECITATION OF EMBODIMENTS

Embodiment 1. A system comprising:
a gas cylinder configured to contain hydrogen gas therein, the hydrogen gas comprising parahydrogen gas at a first concentration of at least 45% and a pressure of at most 40 bar;
wherein the parahydrogen gas has a decay time constant of at least 30 days; and
wherein the parahydrogen gas is for use in a parahydrogen-induced polarization (PHIP), PHIP-sidearm hydrolysis (PHIP-SAH), signal amplification by reversible exchange (SABRE), or PHIP nuclear Overhauser effect system (PHIPNOESYS) nuclear magnetic resonance (NMR) or magnetic resonance imaging (MRI) procedure.

Embodiment 2. The system of Embodiment 1, wherein the first concentration is at least 95%.

Embodiment 3. The system of Embodiment 1 or 2, wherein the pressure is at most 12 bar and wherein the decay time constant is at least 30 days.

Embodiment 4. The system of any one of Embodiments 1-3, wherein the pressure is at most 3 bar and wherein the decay time constant is at least 100 days.

Embodiment 5. The system of any one of Embodiments 1-4, wherein the gas cylinder has been purged with at least one purging operation to containing the hydrogen gas therein.

Embodiment 6. The system of Embodiment 5, wherein the at least one purging operation comprises at least one member selected from the group consisting of: at least one evacuation operation, at least one heating operation, and at least one filling operation.

Embodiment 7. The system of any one of Embodiments 1-6, further comprising a first flow system fluidically coupled to the gas cylinder and to a mixing chamber;
wherein the first flow system is configured to direct the parahydrogen gas to the mixing chamber;
wherein the mixing chamber is configured to contain a first solution therein,
wherein the first solution contains a molecule of interest or a derivative of the molecule of interest;
wherein the molecule of interest is for use in the NMR or MRI procedure; and
wherein the mixing chamber is configured to mix the parahydrogen gas with the molecule of interest or the derivative of the molecule of interest.

Embodiment 8. The system of Embodiment 7, wherein the mixing chamber is configured to mix the parahydrogen gas with the molecule of interest in the presence of a polarization transfer catalyst to thereby transfer spin order from the parahydrogen gas to the molecule of interest via a SABRE interaction.

Embodiment 9. The system of Embodiment 7, wherein the derivative of the molecule of interest comprises at least one double bond or triple bond and wherein the mixing chamber is configured to mix the parahydrogen gas with the derivative of the molecule of interest in the presence of a hydrogenation catalyst to thereby induce a parahydrogenation reaction between the parahydrogen gas and the derivative of the molecule of interest, thereby hydrogenating the at least one double bond or triple bond and forming the molecule of interest and transferring spin order from the parahydrogen gas to the molecule of interest via a PHIP interaction.

Embodiment 10. The system of Embodiment 7, wherein the derivative of the molecule of interest comprises at least one double bond or triple bond and wherein the mixing chamber is configured to mix the parahydrogen gas with the derivative of the molecule of interest in the presence of a hydrogenation catalyst to thereby induce a parahydrogenation reaction between the parahydrogen gas and the derivative of the molecule of interest, thereby hydrogenating the at least one double bond or triple bond and forming a parahydrogenated derivative of the molecule of interest.

Embodiment 11. The system of Embodiment 9, further comprising a second flow system configured fluidically coupled to the mixing chamber and to a hydrolysis chamber;
wherein the second flow system is configured to direct the first solution containing the parahydrogenated derivative of the molecule of interest to the hydrolysis chamber;
wherein the hydrolysis chamber is configured to contain the first solution containing the parahydrogenated derivative of the molecule of interest;
wherein the hydrolysis chamber is configured to mix the first solution containing the parahydrogenated derivative of the molecule of interest with a hydrolysis agent to thereby hydrolyze the parahydrogenated derivative of the molecule of interest to thereby form a hydrolyzed sidearm and the molecule of interest via a PHIP-SAH interaction.

Embodiment 12. The system of any one of Embodiments 7-11, further comprising a third flow system fluidically coupled to the mixing chamber or to the hydrolysis chamber and to a purification chamber;
wherein the third flow system is configured to direct the first solution containing the molecule of interest to the purification chamber.

Embodiment 13. The system of Embodiment 12, wherein the purification chamber is configured to mix the first solution containing the molecule of interest with a second solution to thereby form a third solution containing the molecule of interest, the third solution comprising a reduced concentration of contaminants compared with the first solution.

Embodiment 14. The system of Embodiment 13, wherein the purification chamber is configured to perform a precipitation reaction on the first solution containing the molecule of interest to thereby form a precipitate of the molecule of interest and to mix the precipitate of the molecule of interest with a second solution to thereby form a third solution containing the molecule of interest, the third solution comprising a reduced concentration of contaminants compared with the first solution.

Embodiment 15. The system of any one of Embodiments 7-14, wherein the molecule of interest comprises a biorelevant imaging agent selected from the group consisting of: pyruvate, glutamate, glutamine, lactate, acetate, acetoacetate, zymonate, alanine, fructose, fumarate, bicarbonate, urea, dehydroascorbate, alpha-ketoglutarate, dihydroxyacetone, glucose, ascorbate, and conjugate acids thereof.

Embodiment 16. A method comprising:
containing hydrogen gas within a gas cylinder, the hydrogen gas comprising parahydrogen gas at a first concentration of at least 45% and a pressure of at most 40 bar;
wherein the parahydrogen gas has a decay time constant of at least 30 days; and
wherein the parahydrogen gas is for use in a parahydrogen-induced polarization (PHIP), PHIP-sidearm hydrolysis (PHIP-SAH), signal amplification by reversible exchange (SABRE), or PHIP nuclear Overhauser effect system (PHIPNOESYS) nuclear magnetic resonance (NMR) or magnetic resonance imaging (MRI) procedure.

Embodiment 17. The method of Embodiment 16, wherein the first concentration is at least 95%.

Embodiment 18. The method of Embodiment 16 or 17, wherein the pressure is at most 12 bar and wherein the decay time constant is at least 30 days.

Embodiment 19. The method of any one of Embodiments 16-18, wherein the pressure is at most 3 bar and wherein the decay time constant is at least 100 days.

Embodiment 20. The method of any one of Embodiments 16-19, wherein the gas cylinder has been purged with at least one purging operation prior to containing the hydrogen gas therein.

Embodiment 21. The method of Embodiment 20, wherein the at least one purging operation comprises at least one member selected from the group consisting of: at least one evacuation operation, at least one heating operation, and at least one filling operation.

Embodiment 22. The method of any one of Embodiments 16-21, further comprising mixing the parahydrogen gas with a first solution;
wherein the first solution contains a molecule of interest or a derivative of the molecule of interest; and
wherein the molecule of interest is for use in the NMR or MRI procedure; and

Embodiment 23. The method of Embodiment 22, further comprising mixing the parahydrogen gas with the molecule of interest in the presence of a polarization transfer catalyst to thereby transfer spin order from the parahydrogen gas to the molecule of interest via a SABRE interaction.

Embodiment 24. The method of Embodiment 22, further comprising mixing the parahydrogen gas with the derivative of the molecule of interest in the presence of a hydrogenation catalyst to thereby induce a parahydrogenation reaction between the parahydrogen gas and the derivative of the molecule of interest, thereby hydrogenating at least one double bond or triple bond of the derivative of the molecule of interest, forming the molecule of interest, and transferring spin order from the parahydrogen gas to the molecule of interest via a PHIP interaction.

Embodiment 25. The method of Embodiment 22, further comprising mixing the parahydrogen gas with the derivative of the molecule of interest in the presence of a hydrogenation catalyst to thereby induce a parahydrogenation reaction between the parahydrogen gas and the derivative of the molecule of interest, thereby hydrogenating at least one double bond or triple bond of the derivative of the molecule of interest and forming a parahydrogenated derivative of the molecule of interest.

Embodiment 26. The method of Embodiment 25, further comprising mixing the first solution containing the parahydrogenated derivative of the molecule of interest with a hydrolysis agent to thereby hydrolyze the parahydrogenated derivative of the biomolecule of interest to thereby form a hydrolyzed sidearm and the molecule of interest via a PHIP-SAH interaction.

Embodiment 27. The method of any one of Embodiments 22-26, further comprising purifying the first solution containing the molecule of interest.

Embodiment 28. The method of Embodiment 27, wherein purifying the first solution containing the molecule of interest comprises mixing the first solution containing the molecule of interest with a second solution to thereby form a third solution containing the molecule of interest, the third solution comprising a reduced concentration of contaminants compared with the first solution.

Embodiment 29. The method of Embodiment 27, wherein purifying the first solution containing the molecule of interest comprises performing a precipitation reaction on the first solution containing the molecule of interest to thereby form a precipitate of the molecule of interest and mixing the precipitate of the molecule of interest with a second solution to thereby form a third solution containing the molecule of interest, the third solution comprising a reduced concentration of contaminants compared with the first solution.

Embodiment 30. The method of any one of Embodiments 22-29, wherein the molecule of interest comprises a biorelevant imaging agent selected from the group consisting of: pyruvate, glutamate, glutamine, lactate, acetate, acetoacetate, zymonate, alanine, fructose, fumarate, bicarbonate, urea, dehydroascorbate, alpha-ketoglutarate, dihydroxyacetone, glucose, ascorbate, and conjugate acids thereof.

Embodiment 31. A system comprising:
a cryogenic container configured to contain liquid hydrogen therein; and
a chamber fluidically coupled to the cryogenic container, the chamber configured to receive the liquid hydrogen from the cryogenic container and to boil the received liquid hydrogen, thereby forming a first hydrogen gas comprising at least 50, 55, 60, 65, 70, 75, 80, 85, 90, or 95 mole percent parahydrogen gas.

Embodiment 32. The system of Embodiment 31, further comprising a port fluidically coupled to the chamber, the port configured to fluidically couple the chamber to a gas cylinder or to a fluid pump.

Embodiment 33. The system of Embodiment 32, wherein the gas cylinder or the fluid pump is configured to deliver the first hydrogen gas to a solution, the solution comprising a precursor to a target molecule and a catalyst, to thereby hydrogenate the precursor in the presence of the catalyst and thereby form the target molecule.

Embodiment 34. The system of Embodiment 33, wherein the precursor comprises a parahydrogen induced polarization (PHIP) precursor or a PHIP-sidearm hydrogenation (PHIP-SAH) precursor.

Embodiment 35. The system of any one of Embodiments 31-34, wherein the chamber comprises a heater configured to boil the received liquid hydrogen.

Embodiment 36. The system of any one of Embodiments 31-35, wherein the liquid hydrogen comprises at least 50, 55, 60, 65, 70, 75, 80, 85, 90, or 95 mole percent liquid parahydrogen.

Embodiment 37. The system of any one of Embodiments 31-36, wherein the cryogenic container is further configured to contain a first parahydrogen conversion catalyst therein, wherein the first parahydrogen conversion catalyst is configured to convert liquid orthohydrogen to liquid parahydrogen.

Embodiment 38. The system of any one of Embodiments 31-36, further comprising:
a gas-tight container configured to contain a second hydrogen gas therein and to convert gaseous orthohydrogen in the second hydrogen gas to gaseous parahydrogen to thereby generate a third hydrogen gas comprising at least 50, 55, 60, 65, 70, 75, 80, 85, 90, or 95 mole percent gaseous parahydrogen; and
a condenser configured to receive the third hydrogen gas and to generate the liquid hydrogen therefrom, wherein the condenser is fluidically coupled to the cryogenic container and configured to deliver the liquid hydrogen to the cryogenic container.

Embodiment 39. The system of Embodiment 38, wherein the gas-tight container is further configured to contain a second parahydrogen conversion catalyst therein, wherein the second parahydrogen conversion catalyst is configured to convert the gaseous orthohydrogen to the gaseous parahydrogen.

Embodiment 40. The system of Embodiment 37 or 39, wherein the first or second parahydrogen conversion catalyst comprises a material configured to adsorb the liquid or gaseous orthohydrogen, to split the liquid or gaseous orthohydrogen, and to release the liquid or gaseous orthohydrogen.

Embodiment 41. The system of Embodiment 37 or 39, wherein the liquid or gaseous orthohydrogen comprises two hydrogen spins, and wherein the first or second parahydrogen conversion catalyst comprises a paramagnetic material configured to break a symmetry between the two hydrogen spins to thereby convert the liquid or gaseous orthohydrogen to the liquid or gaseous parahydrogen.

Embodiment 42. The system of Embodiment 37, 39, 40, or 41, wherein the first or second parahydrogen conversion catalyst comprises at least one material selected from the group consisting of: gadolinium oxide, crude ceric oxide, neodymium oxide, FeCl₂ on silica gel, paramagnetic Fe₂O₃ on porous glass, 2% paramagnetic Fe₂O₃ on porous glass, paramagnetic Fe₂O₃ on Florex, 15% paramagnetic Fe₂O₃ on Florex, ferric ammonium sulfate, magnetite, Fe₃O₄, Cr₂O₃ on alumina, paramagnetic Fe₂O₃ and Cr₂O₃ on alumina, 15% paramagnetic Fe₂O₃ and 9.3% Cr₂O₃ on alumina, Ni and thoria on alumina, 5.3% Ni and 0.24% thoria on alumina, MnO₂ on silica gel, 18% MnO₂ on silica gel, Ni on alumina, 0.5% Ni on alumina, hydrous manganese dioxide, hydrous ferric oxide, and hydrated iron oxide.

Embodiment 43. A method comprising:
receiving liquid hydrogen; and
boiling the liquid hydrogen to thereby form a first hydrogen gas comprising at least 50, 55, 60, 65, 70, 75, 80, 85, 90, or 95 mole percent parahydrogen gas.

Embodiment 44. The method of Embodiment 43, further comprising delivering the first hydrogen gas to a solution, the solution comprising a precursor to a target molecule and a catalyst.

Embodiment 45. The method of Embodiment 44, further comprising using the first hydrogen gas to hydrogenate the precursor in the presence of the catalyst to thereby form the target molecule.

Embodiment 46. The method of Embodiment 45, wherein the precursor comprises a parahydrogen induced polarization (PHIP) precursor or a PHIP-sidearm hydrogenation (PHIP-SAH) precursor.

Embodiment 47. The method of any one of Embodiments 44-46, further comprising delivering the target molecule to a subject or to a sample and obtaining a nuclear magnetic resonance (NMR) spectrum or magnetic resonance imaging (MRI) image of the subject or sample in response to the target molecule.

Embodiment 48. The method of any one of Embodiments 43-47, further comprising using a first parahydrogen conversion catalyst configured to convert liquid orthohydrogen to liquid parahydrogen.

Embodiment 49. The method of any one of Embodiments 43-47, further comprising:
obtaining a second hydrogen gas;
converting gaseous orthohydrogen in the second hydrogen gas to gaseous parahydrogen to thereby generate a third hydrogen gas comprising at least 50, 55, 60, 65, 70, 75, 80, 85, 90, or 95 mole percent gaseous parahydrogen; and
condensing the third hydrogen gas to generate the liquid hydrogen therefrom.

Embodiment 50. The method of Embodiment 49, further comprising using a second parahydrogen conversion catalyst to convert the gaseous orthohydrogen to the gaseous parahydrogen.

Embodiment 51. The method of Embodiment 48 or 50, wherein the first or second parahydrogen conversion catalyst comprises a material configured to adsorb the liquid or gaseous orthohydrogen, to split the liquid or gaseous orthohydrogen, and to release the liquid or gaseous orthohydrogen.

Embodiment 52. The method of Embodiment 48 or 50, wherein the liquid or gaseous orthohydrogen comprises two hydrogen spins, and wherein the first or second parahydrogen conversion catalyst comprises a paramagnetic material configured to break a symmetry between the two hydrogen spins to thereby convert the liquid or gaseous orthohydrogen to the liquid or gaseous parahydrogen.

Embodiment 53. The method of Embodiment 48, 50, 51, or 52, wherein the first or second parahydrogen conversion catalyst comprises at least one material selected from the group consisting of: gadolinium oxide, crude ceric oxide, neodymium oxide, FeCl₂ on silica gel, paramagnetic Fe₂O₃ on porous glass, 2% paramagnetic Fe₂O₃ on porous glass, paramagnetic Fe₂O₃ on Florex, 15% paramagnetic Fe₂O₃ on Florex, ferric ammonium sulfate, magnetite, Fe₃O₄, Cr₂O₃ on alumina, paramagnetic Fe₂O₃ and Cr₂O₃ on alumina, 15% paramagnetic Fe₂O₃ and 9.3% Cr₂O₃ on alumina, Ni and thoria on alumina, 5.3% Ni and 0.24% thoria on alumina, MnO₂ on silica gel, 18% MnO₂ on silica gel, Ni on alumina, 0.5% Ni on alumina, hydrous manganese dioxide, hydrous ferric oxide, and hydrated iron oxide.

1. A system comprising:
a gas cylinder configured to contain hydrogen gas therein, the hydrogen gas comprising parahydrogen gas at a first concentration of at least 45% and a pressure of at most 40 bar;
wherein the parahydrogen gas has a decay time constant of at least 30 days; and
wherein the parahydrogen gas is for use in a parahydrogen-induced polarization (PHIP), PHIP-sidearm hydrolysis (PHIP-SAH), signal amplification by reversible exchange (SABRE), or PHIP nuclear Overhauser effect system (PHIPNOESYS) nuclear magnetic resonance (NMR) or magnetic resonance imaging (MRI) procedure.

2. The system of claim 1, wherein the first concentration is at least 95%.

3. The system of claim 1, wherein the pressure is at most 12 bar and wherein the decay time constant is at least 30 days.

4. The system of claim 1, wherein the pressure is at most 3 bar and wherein the decay time constant is at least 100 days.

5. The system of claim 1, wherein the gas cylinder has been purged with at least one purging operation to containing the hydrogen gas therein.

6. The system of claim 5, wherein the at least one purging operation comprises at least one member selected from the group consisting of: at least one evacuation operation, at least one heating operation, and at least one filling operation.

7. The system of claim 1, further comprising a first flow system fluidically coupled to the gas cylinder and to a mixing chamber;
wherein the first flow system is configured to direct the parahydrogen gas to the mixing chamber;
wherein the mixing chamber is configured to contain a first solution therein,
wherein the first solution contains a molecule of interest or a derivative of the molecule of interest;
wherein the molecule of interest is for use in the NMR or MRI procedure; and
wherein the mixing chamber is configured to mix the parahydrogen gas with the molecule of interest or the derivative of the molecule of interest.

8. The system of claim 7, wherein the mixing chamber is configured to mix the parahydrogen gas with the molecule of interest in the presence of a polarization transfer catalyst to thereby transfer spin order from the parahydrogen gas to the molecule of interest via a SABRE interaction.

9. The system of claim 7, wherein the derivative of the molecule of interest comprises at least one double bond or triple bond and wherein the mixing chamber is configured to mix the parahydrogen gas with the derivative of the molecule of interest in the presence of a hydrogenation catalyst to thereby induce a parahydrogenation reaction between the parahydrogen gas and the derivative of the molecule of interest, thereby hydrogenating the at least one double bond or triple bond and forming the molecule of interest and transferring spin order from the parahydrogen gas to the molecule of interest via a PHIP interaction.

10. The system of claim 7, wherein the derivative of the molecule of interest comprises at least one double bond or triple bond and wherein the mixing chamber is configured to mix the parahydrogen gas with the derivative of the molecule of interest in the presence of a hydrogenation catalyst to thereby induce a parahydrogenation reaction between the parahydrogen gas and the derivative of the molecule of interest, thereby hydrogenating the at least one double bond or triple bond and forming a parahydrogenated derivative of the molecule of interest.

11. The system of claim 9, further comprising a second flow system configured fluidically coupled to the mixing chamber and to a hydrolysis chamber;
wherein the second flow system is configured to direct the first solution containing the parahydrogenated derivative of the molecule of interest to the hydrolysis chamber;
wherein the hydrolysis chamber is configured to contain the first solution containing the parahydrogenated derivative of the molecule of interest;
wherein the hydrolysis chamber is configured to mix the first solution containing the parahydrogenated derivative of the molecule of interest with a hydrolysis agent to thereby hydrolyze the parahydrogenated derivative of the molecule of interest to thereby form a hydrolyzed sidearm and the molecule of interest via a PHIP-SAH interaction.

12. The system of claim 7, further comprising a third flow system fluidically coupled to the mixing chamber or to the hydrolysis chamber and to a purification chamber;
wherein the third flow system is configured to direct the first solution containing the molecule of interest to the purification chamber.

13. The system of claim 12, wherein the purification chamber is configured to mix the first solution containing the molecule of interest with a second solution to thereby form a third solution containing the molecule of interest, the third solution comprising a reduced concentration of contaminants compared with the first solution.

14. The system of claim 13, wherein the purification chamber is configured to perform a precipitation reaction on the first solution containing the molecule of interest to thereby form a precipitate of the molecule of interest and to mix the precipitate of the molecule of interest with a second solution to thereby form a third solution containing the molecule of interest, the third solution comprising a reduced concentration of contaminants compared with the first solution.

15. A system comprising:
a cryogenic container configured to contain liquid hydrogen therein; and
a chamber fluidically coupled to the cryogenic container, the chamber configured to receive the liquid hydrogen from the cryogenic container and to boil the received liquid hydrogen, thereby forming a first hydrogen gas comprising at least 50, 55, 60, 65, 70, 75, 80, 85, 90, or 95 mole percent parahydrogen gas.

16. The system of claim 15, further comprising a port fluidically coupled to the chamber, the port configured to fluidically couple the chamber to a gas cylinder or to a fluid pump.

17. The system of claim 16, wherein the gas cylinder or the fluid pump is configured to deliver the first hydrogen gas to a solution, the solution comprising a precursor to a target molecule and a catalyst, to thereby hydrogenate the precursor in the presence of the catalyst and thereby form the target molecule.

18. The system of claim 17, wherein the precursor comprises a parahydrogen induced polarization (PHIP) precursor or a PHIP-sidearm hydrogenation (PHIP-SAH) precursor.

19. The system of claim 15, wherein the chamber comprises a heater configured to boil the received liquid hydrogen.

20. The system of claim 15, wherein the liquid hydrogen comprises at least 50, 55, 60, 65, 70, 75, 80, 85, 90, or 95 mole percent liquid parahydrogen.

21. The system of claim 15, wherein the cryogenic container is further configured to contain a first parahydrogen conversion catalyst therein, wherein the first parahydrogen conversion catalyst is configured to convert liquid orthohydrogen to liquid parahydrogen.

22. The system of claim 15, further comprising:
a gas-tight container configured to contain a second hydrogen gas therein and to convert gaseous orthohydrogen in the second hydrogen gas to gaseous parahydrogen to thereby generate a third hydrogen gas comprising at least 50, 55, 60, 65, 70, 75, 80, 85, 90, or 95 mole percent gaseous parahydrogen; and
a condenser configured to receive the third hydrogen gas and to generate the liquid hydrogen therefrom, wherein the condenser is fluidically coupled to the cryogenic container and configured to deliver the liquid hydrogen to the cryogenic container.

23. The system of claim 22, wherein the gas-tight container is further configured to contain a second parahydrogen conversion catalyst therein, wherein the second parahydrogen conversion catalyst is configured to convert the gaseous orthohydrogen to the gaseous parahydrogen.

24. The system of claim 21 or 23, wherein the first or second parahydrogen conversion catalyst comprises a material configured to adsorb the liquid or gaseous orthohydrogen, to split the liquid or gaseous orthohydrogen, and to release the liquid or gaseous orthohydrogen.

25. The system of claim 21 or 23, wherein the liquid or gaseous orthohydrogen comprises two hydrogen spins, and wherein the first or second parahydrogen conversion catalyst comprises a paramagnetic material configured to break a symmetry between the two hydrogen spins to thereby convert the liquid or gaseous orthohydrogen to the liquid or gaseous parahydrogen.

26. The system of claim 21 or 23, wherein the first or second parahydrogen conversion catalyst comprises at least one material selected from the group consisting of: gadolinium oxide, crude ceric oxide, neodymium oxide, FeCl₂ on silica gel, paramagnetic Fe₂O₃ on porous glass, 2% paramagnetic Fe₂O₃ on porous glass, paramagnetic Fe₂O₃ on Florex, 15% paramagnetic Fe₂O₃ on Florex, ferric ammonium sulfate, magnetite, Fe₃O₄, Cr₂O₃ on alumina, paramagnetic Fe₂O₃ and Cr₂O₃ on alumina, 15% paramagnetic Fe₂O₃ and 9.3% Cr₂O₃ on alumina, Ni and thoria on alumina, 5.3% Ni and 0.24% thoria on alumina, MnO₂ on silica gel, 18% MnO₂ on silica gel, Ni on alumina, 0.5% Ni on alumina, hydrous manganese dioxide, hydrous ferric oxide, and hydrated iron oxide.
